(19) United States
(12) Patent Application Publication
(10) Pub. No.: US 2025/0016994 A1
(43) Pub. Date: Jan. 9, 2025

(54) SEMICONDUCTOR DEVICE

(71) Applicant: Samsung Electronics Co., Ltd., Suwon-si (KR)

(72) Inventors: Heejae CHAE, Suwon-si (KR); Hyunjin LEE, Suwon-si (KR); Yun CHOI, Suwon-si (KR)

(73) Assignee: Samsung Electronics Co., Ltd., Suwon-si (KR)

(21) Appl. No.: 18/668,431

(22) Filed: May 20, 2024

(30) Foreign Application Priority Data
Jul. 4, 2023 (KR) 10-2023-0086200

(51) Int. Cl. H10B 12/00

(52) U.S. Cl. CPC H10B 12/485; H10B 12/053; H10B 12/315; H10B 12/33

(57) ABSTRACT

The semiconductor includes a substrate including first active patterns, the substrate defining trenches between the first active patterns; an upper silicon pattern on an upper sidewall of at least a portion of each of the first active patterns; and a first contact plug contacting an edge portion in a longitudinal direction of each of the first active patterns, a sidewall of the first contact plug contacting at least a portion of the upper silicon pattern, and the first contact plug having a bottom lower than a bottom of the upper silicon pattern.

### CROSS-REFERENCE TO RELATED APPLICATION

This application claims priority under 35 USC § 119 to Korean Patent Application No. 10-2023-0086200, filed on Jul. 4, 2023, in the Korean Intellectual Property Office (KIPO), the contents of which are incorporated by reference herein in their entirety.

### BACKGROUND

Various example embodiments relate to semiconductor device. Particularly, various example embodiments relate to DRAM (Dynamic random-access memory) devices.

As a semiconductor device is more highly integrated, a contact area between an active pattern and a contact plug may be greatly decreased. Accordingly, in the semiconductor device, it may be desired to increase the contact area between the active pattern and the contact plug and to decrease a contact resistance between the active pattern and the contact plug.

### SUMMARY

Various example embodiments provide semiconductor devices having excellent characteristics.

According to some example embodiments, there is provided a semiconductor device. The semiconductor includes a substrate including first active patterns, the substrate defining trenches between the first active patterns; an upper silicon pattern on an upper sidewall of at least a portion of each of the first active patterns; and a first contact plug contacting an edge portion in a longitudinal direction of each of the first active patterns, a sidewall of the first contact plug contacting at least a portion of the upper silicon pattern, and the first contact plug having a bottom lower than a bottom of the upper silicon pattern.

According to some example embodiments, there is provided a semiconductor device.

The semiconductor includes a substrate; first trenches on defined by a first region of the substrate; first active patterns between the first trenches; second trenches defined by a second region of the substrate; second active patterns between the second trenches; a first device isolation pattern in the first trenches; a second device isolation pattern in the second trenches; an upper silicon pattern on an upper sidewall of at least a portion of each of the first active patterns; a gate structure in the substrate of the first region, extending in a first direction; a bit line structure on the first region of the substrate, extending in a second direction perpendicular to the first direction, and contacting a central portion in a longitudinal direction of the first active pattern; and a first contact plug contacting an edge portion in the longitudinal direction of the first active patterns, a sidewall of the first contact plug contacting at least a portion of the upper silicon pattern, and the first contact plug having a bottom lower than a bottom of the upper silicon pattern.

According to some example embodiments, there is provided a semiconductor device. The semiconductor includes a substrate, first trenches defined by the substrate; first active patterns between the first trenches; a first device isolation pattern in the first trenches, an upper surface of the first device isolation being lower than upper surfaces of the first active patterns;
an upper silicon pattern on an upper sidewall of the first active patterns above the upper surface of the first device isolation pattern; a capping insulation pattern between the upper silicon patterns on the first device isolation pattern; a gate structure in the substrate, extending in a first direction; a bit line structure on the substrate, extending in a second direction perpendicular to the first direction, and contacting a central portion in a longitudinal direction of the first active patterns; and a first contact plug contacting an edge portion in the longitudinal direction of the first active patterns, a sidewall of the first contact plug contacting at least a portion of the upper silicon pattern, and the first contact plug having a bottom lower than a bottom of the upper silicon pattern.

In various example embodiments, the first contact plug may contact the first active pattern and the upper silicon pattern. Accordingly, a contact area between the first contact plug and the active region may be increased, and a contact resistance between the first contact plug and the active region may be decreased. Additionally, the upper silicon pattern may be formed only on a portion of the upper sidewall of the first active pattern. Therefore, a stress of the first active pattern due to forming the upper silicon pattern may be decreased. Accordingly, the semiconductor device may have excellent characteristics.

### BRIEF DESCRIPTION OF THE DRAWINGS

Various example embodiments will be more clearly understood from the following detailed description taken in conjunction with the accompanying drawings. FIGS. 1 to 38 represent various non-limiting, example embodiments as described herein.

FIGS. 1 to 29 are cross-sectional views and plan views illustrating a method of manufacturing a semiconductor device in accordance with various example embodiments;

FIGS. 30 to 34 are cross-sectional views illustrating a method for manufacturing a semiconductor device according to example embodiments; and

FIGS. 35 to 38 are cross-sectional views and plan views illustrating a method for manufacturing a semiconductor device according to example embodiments.

### DETAILED DESCRIPTION

Hereinafter, various example embodiments will be described in detail with reference to the accompanying drawings.

Hereinafter, two directions parallel to an upper surface of a substrate and perpendicular to each other are referred to as a first direction and a second direction, respectively. Additionally, a direction parallel to the upper surface of the substrate and oblique to the first direction (for example, in a diagonal direction) is referred to as a third direction.

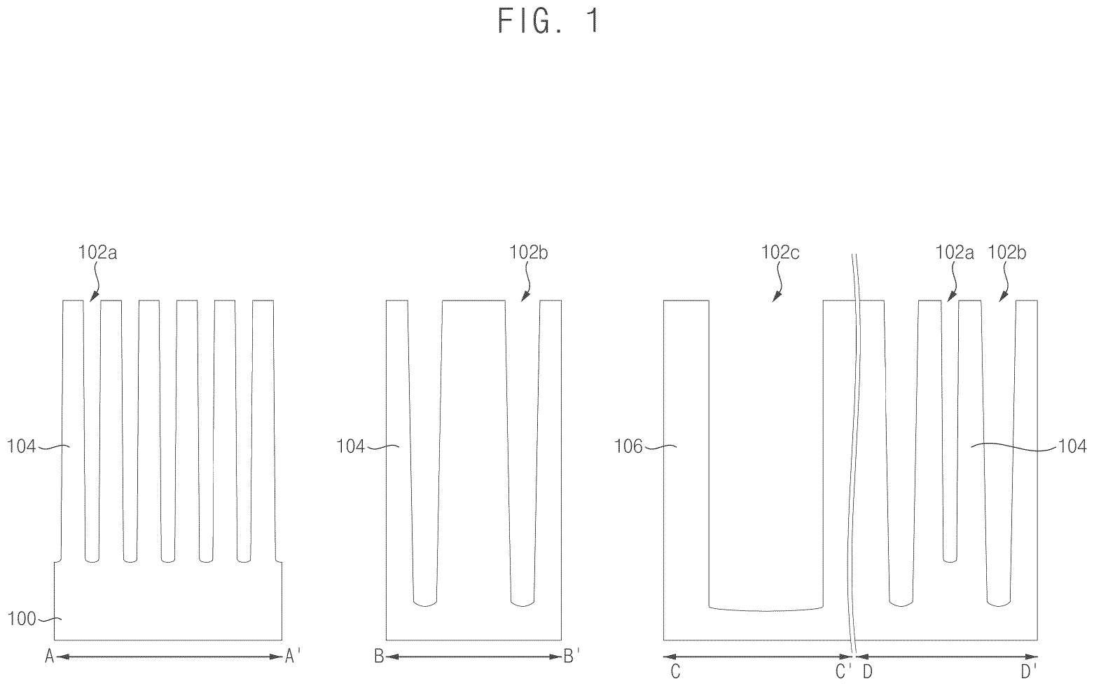

FIGS. 1 to 29 are cross-sectional views and plan views illustrating a method of manufacturing a semiconductor device in accordance with various example embodiments.

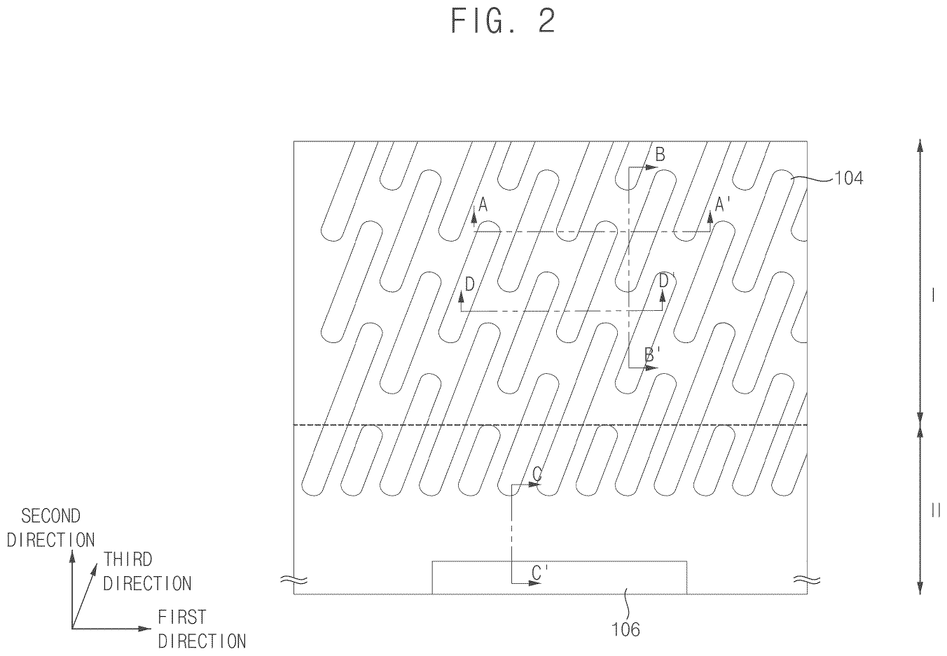

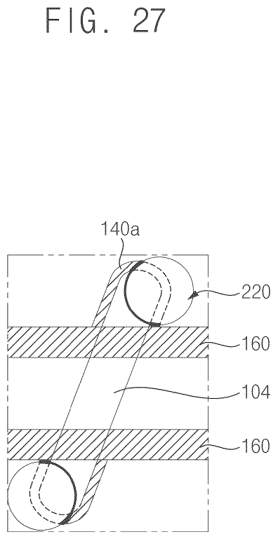

FIGS. 1, 3 to 8, 10, 12, 13, 15 to 17, 19, 21, 22, 24, 25, 28 and 29 are cross-sectional views. FIGS. 2, 9, 11, 14, 18, 20, 23 and 26 are plan views. FIG. 27 is an enlarged plan view illustrating a portion of the semiconductor device. The cross-sectional views may include views cut along lines A-A′, B-B′, C-C′, and D-D′ of the plan views.

Referring to FIGS. 1 and 2, a substrate 100 may include a first region I and a second region II. The first region I may include a cell region, and the second region II may include an interface region and a core/peripheral region.

The cell region may be a region in which memory cells are formed, and the core/peripheral region may be a region in which peripheral circuits or core circuits are formed. The interface region may be positioned at an interface between the cell region and the core/peripheral region, and dummy cells may be formed on the interface region. In each of the cross-sectional views, cross-sections A-A′, B-B′, and D-D′ may represent the cell region I, and cross-section D-D′ may represent the second region II.

A first mask pattern may be formed on the substrate 100, and a field region of the substrate 100 may be etched using the first mask pattern to form trenches 102a, 102b, and 102c. A protruding portion of the substrate 100 between the trenches 102a, 102b, and 102c may be defined as an active pattern. An upper surface of the active pattern may serve as an active region.

First active patterns 104 may be formed on the first region I of the substrate 100, and the first active patterns 104 may have an isolated shape extending in the third direction. The third direction may be a longitudinal direction of the first active pattern 104. The first active patterns 104 may be regularly arranged in each of the first direction and the second direction. The first active patterns 104 may be spaced apart from each other in each of the first direction and the second direction. The first active patterns 104 may have a high aspect ratio. In example embodiments, an aspect ratio (a vertical height:a horizontal width) may be 7 or more: 1, for example, 7:1, 10:1, etc.

In example embodiments, cell trenches 102a and 102b and the first active patterns 104 may be formed on the first region I. In each of the cross sectional view, internal widths of the cell trenches 102a and 102b may vary depending on spacing between the first active patterns 104. The internal widths of the cell trenches 102a and 102b may be different depending on positions of the upper surface of the substrate 100. In example embodiments, the cell trenches may include a first trench 102a having a first width that is a narrowest width and a second trench 102b having a second width greater than the first width.

A third trench 102c and a second active pattern 106 may be formed on the second region II. The third trench 102c may have a width greater than the second trench 102b.

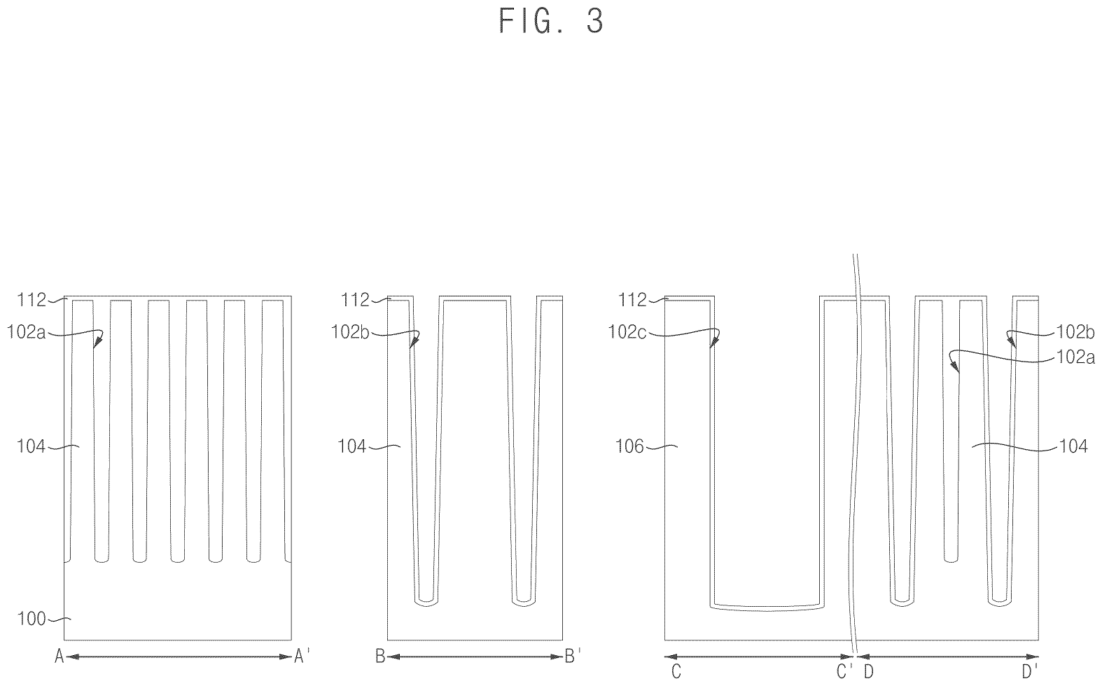

Referring to FIG. 3, a first insulation layer 112 may be conformally formed on inner surfaces of the first to third trenches 102a, 102b, and 102c and the upper surface of the substrate 100. The first insulation layer 112 may be formed to completely fill the first trench 102a. However, the first insulation layer 112 may not completely fill (for example, partially fill) the second and third trenches 102b and 102c having widths greater than the width of the first trench 102a. The first insulation layer 112 may be formed along surface profiles of the second and third trenches 102b and 102c and the substrate 100.

The first insulation layer 112 may include, for example, silicon oxide. In example embodiments, the first insulation layer 112 may be formed by atomic layer deposition process or the like.

A process for forming a silicon layer (for example, polysilicon layer) may not be performed before performing the process for forming the first insulation layer 112. Therefore, when the silicon layer is formed, defects, such as bending of the first active patterns 104 or structural instability caused by stress, may be decreased.

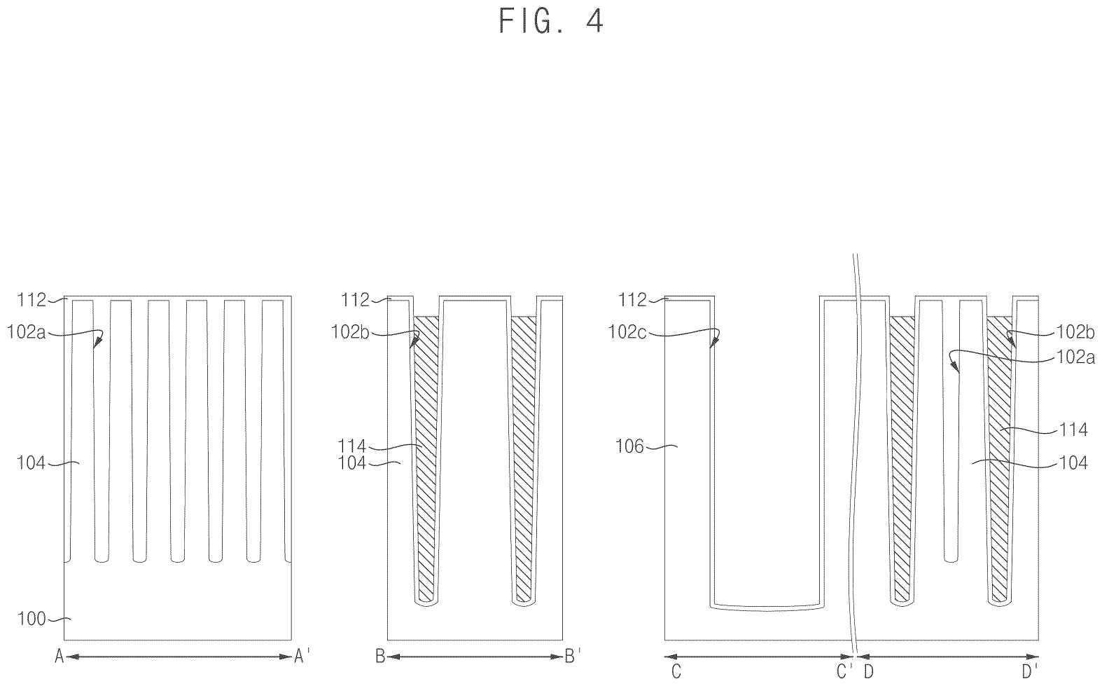

Referring to FIG. 4, a second insulation layer may be conformally formed on the first insulation layer 112. The second insulation layer may include a material different from a material of the first insulation layer.

The second insulation layer may completely fill the second trench 102b. However, the second insulation layer may not completely fill the third trench 102c. The second insulation layer may partially fill the third trench 102c. The second insulation layer may be conformally formed along the surface profile of the third trench 102c. The second insulation layer may include, for example, silicon nitride.

Thereafter, the second insulation layer may be removed to a predetermined (or, alternatively, desired or selected) thickness. The removing process may include an isotropic etching process or a cleaning process.

In the removing process, the second insulation layer formed on the first trenches 102a and 102b and the first active patterns 104 of the first region I and the second insulation layer formed on the third trench 102c and the second active pattern 106 of the second region II may be removed.

However, the second insulation layer may fill the second trench 102b on the first region I, so that the second insulation layer may be formed to have a thick thickness in a vertical direction perpendicular to the surface of the substrate 100. For example, the second insulation layer inside the second trench 102b may be at least as thick as a depth of the second trench. Therefore, the second insulation layer may remain only in the second trench 102b, after the removing process. Accordingly, a second insulation layer pattern 114 may be formed in the second trench 102b. An upper surface of the second insulation layer pattern 114 may be lower than an upper surface of the first active pattern 104 adjacent to both sides of the second insulation layer pattern 114.

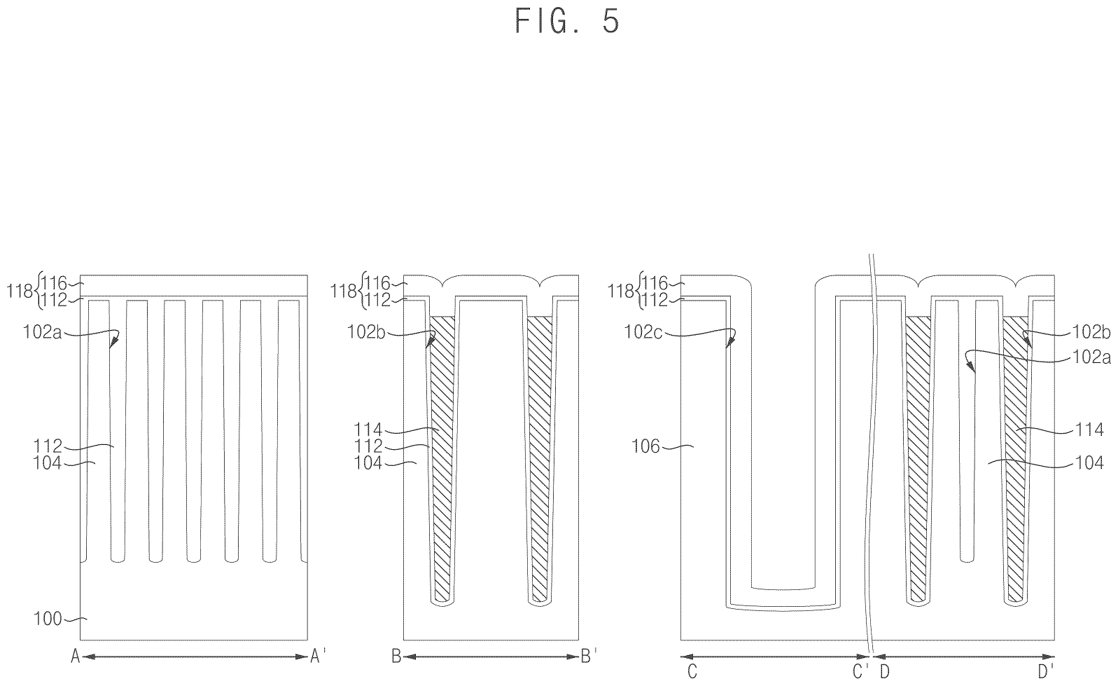

Referring to FIG. 5, a third insulation layer 116 may be formed on upper surfaces of the first insulation layer 112 and the second insulation layer pattern 114.

The third insulation layer 116 may partially fill the third trench 102c. The third insulation layer 116 may be formed conformally along the surface profile of the third trench 102c. The third insulation layer 116 may include, for example, silicon oxide.

The third insulation layer 116 may be formed on the upper surface of the second insulation layer pattern 114 to fill the second trench 102b. A recess may be formed on the upper surface of the third insulation layer 116 facing to the second trench 102b. Accordingly, the upper surface of the third insulation layer 116 on the first region I may not be flat, and may have locally curved portions, for example, at or around the second trench 102b.

Since the first insulation layer 112 and the third insulation layer 116 include the same material, the first insulation layer 112 and the third insulation layer 116 may be merged with each other. The first and third insulation layers 112 and 116, which may be merged or distinct, may be referred to as a first filling insulation layer 118.

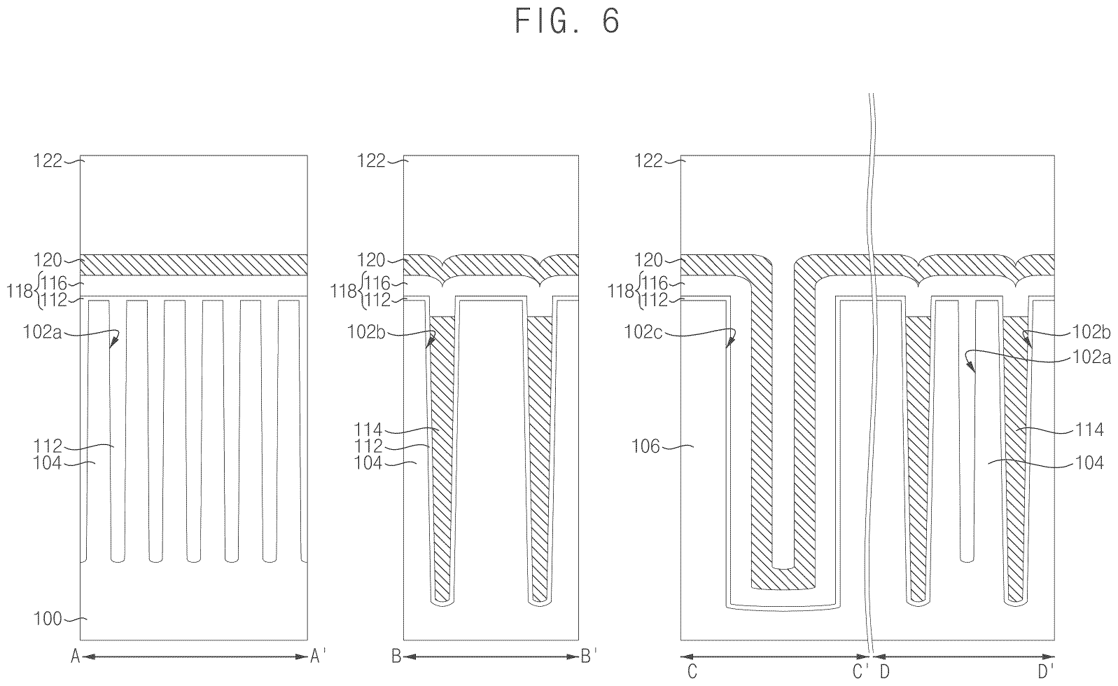

Referring to FIG. 6, a second filling insulation layer 120 including a material different from a material of the first filling insulation layer 118 may be formed on the first filling insulation layer 118.

The second filling insulation layer 120 may partially fill the third trench 102c. The second filling insulation layer 120 may be formed along the surface profile of the third trench 102c. The second filling insulation layer 120 may include, for example, silicon nitride.

A third filling insulation layer 122 including a material different from the material of the second filling insulation layer 120 may be formed on the second filling insulation layer 120.

The third filling insulation layer 122 may be formed to completely fill the third trench 102c. The third filling insulation layer 122 may include the material having an excellent gap filling characteristic. The third filling insulation layer 122 may include, for example, silicon oxide.

In example embodiments, the second filling insulation layer 120 and the third filling insulation layer 122 may not fill the first and second trenches 102a and 102b on the first region I. The first to third filling insulation layers 118, 120, and 122 may be sequentially stacked on surfaces of the third trench 102c on the second region II.

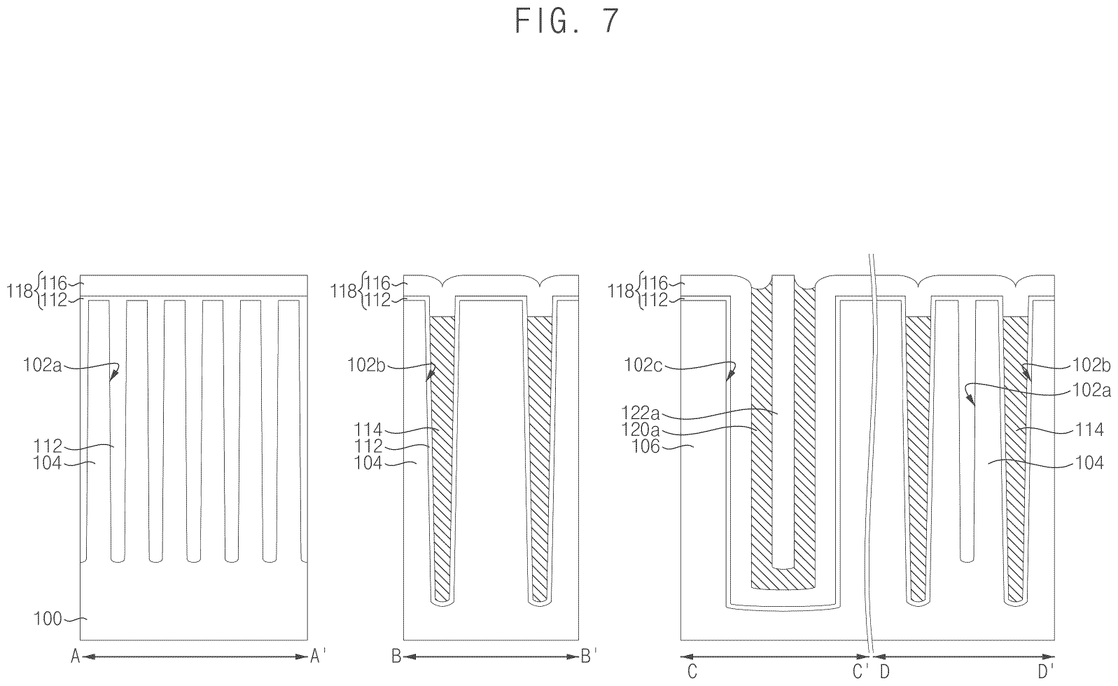

Referring to FIG. 7, the third filling insulation layer 122 may be planarized until an upper surface of the second filling insulation layer 120 on the first region may be exposed. In example embodiments, the planarization process may include a chemical mechanical polishing (CMP) process and/or an etch back process.

By the planarization process, entire of the third filling insulation layer 122 on the first region I may be removed, and the second filling insulation layer 120 may be exposed. However, the third filling insulation layer 122 formed in the third trench 102c on the second region II may remain, so that the third filling insulation layer 122 may be transformed into a third filling insulation layer pattern 122a. An upper surface of the third filling insulation layer pattern 122a may be higher than the upper surface of the substrate 100.

Additionally, a portion of the second filling insulation layer 120 may be removed so as to expose the first filling insulation layer 118 on the first region I. The removing process of the second filling insulation layer 120 may be performed by a wet etching or a wet cleaning process or the like.

In the removing process, an entirety of the second filling insulation layer 120 on the first region I may be removed. However, the second filling insulation layer 120 formed in the third trench 102c on the second region II may remain, so that the second filling insulation layer 120 may be transformed into a second filling insulation layer pattern 120a.

Accordingly, the first filling insulation layer 118, the second filling insulation layer pattern 120a, and the third filling insulation layer pattern 122a on the second region II may be exposed after the above processes. The first filling insulation layer 118, the second filling insulation layer pattern 120a, and the third filling insulation layer pattern 122a may fill the third trench 102c on the second region II.

The first filling insulation layer 118 may fill the first trench 102a on the first region I. The first filling insulation layer 118 and the second insulation layer pattern 114 may fill the second trench 102b on the first region I.

The first filling insulation layer 118, the second and third filling insulation layer patterns 120a and 122a, and the second insulation layer pattern 114 formed in the first to third trenches 102a, 102b, and 102c may be collectively referred to as device isolation patterns. A stacked structure of the device isolation pattern formed in each of the first to third trenches 102a, 102b, and 102c may not be limited to thereto.

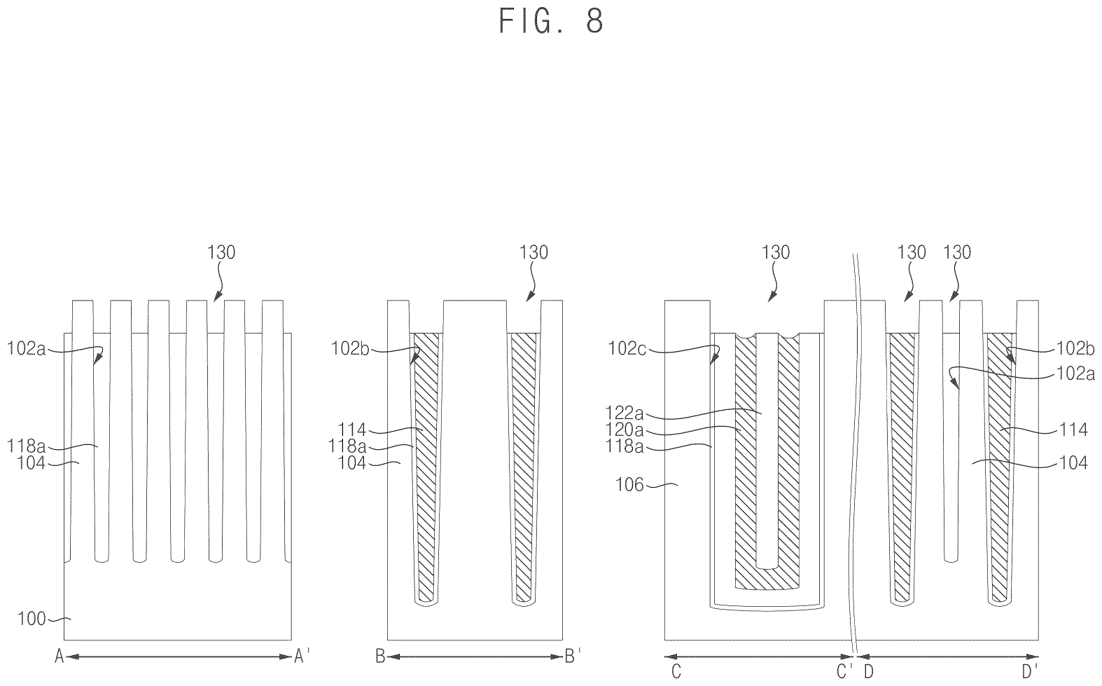

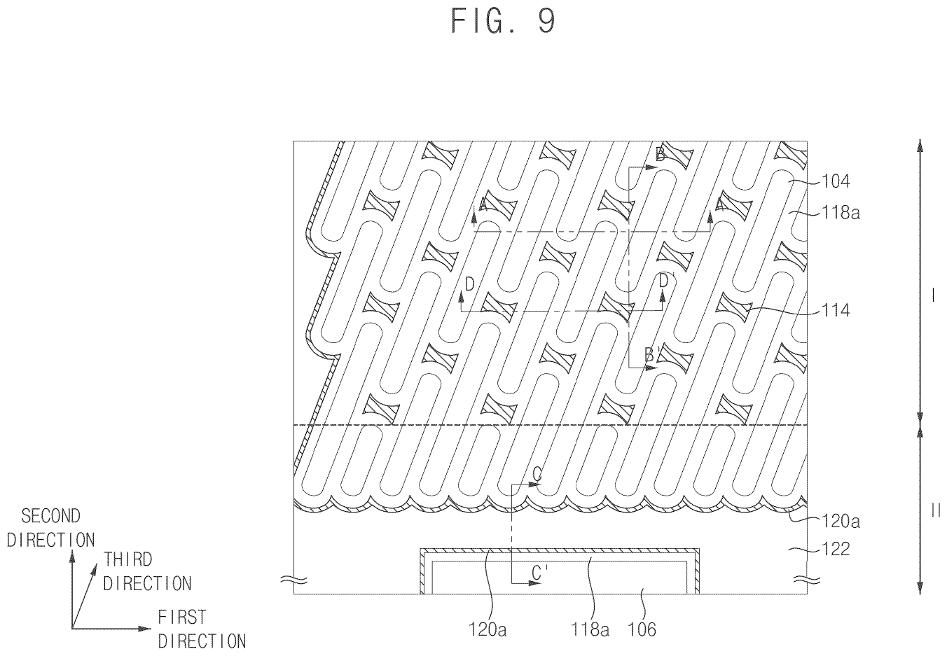

Referring to FIGS. 8 and 9, upper portions of the first filling insulation layer 118, the second insulation layer pattern 114 on the first region I and the first filling insulation layer 118, the first filling insulation layer 118 and the third filling insulation layer pattern 122a on the second region II may be removed so as to expose the upper surfaces and upper sidewalls of the first active pattern 104 and the second active pattern 106. Accordingly, a first filling insulation layer pattern 118a may be formed in the first trench 102a. The first filling insulation layer pattern 118a and a second insulation layer pattern 114 may be formed in the second trench 102b. The first filling insulation layer pattern 118a, the second filling insulation layer pattern 120a, and the third filling insulation layer pattern 122a may be formed in the third trench 102c.

When the removing process is performed, first recesses 130 may be formed between the first active patterns 104 and between the second active patterns 106. Upper surfaces of the device isolation patterns may be exposed by a bottom of each of the first recesses 130.

In example embodiments, in the first region I, an upper surface of the first filling insulation layer pattern 118a may be exposed by the first recess 130 corresponding to the first trench 102a. In the first region I, upper surfaces of the first filling insulation layer pattern 118a and the second filling insulation layer pattern may be exposed by the first recess 130 corresponding to the second trench 102a. Upper surfaces of the first filling insulation layer pattern 118a, the second filling insulation layer pattern 120a, and the third filling insulation layer pattern 122a may be exposed by the bottom of the first recess 130 on the second region II.

The removing process may include an etch-back process or a wet etching process.

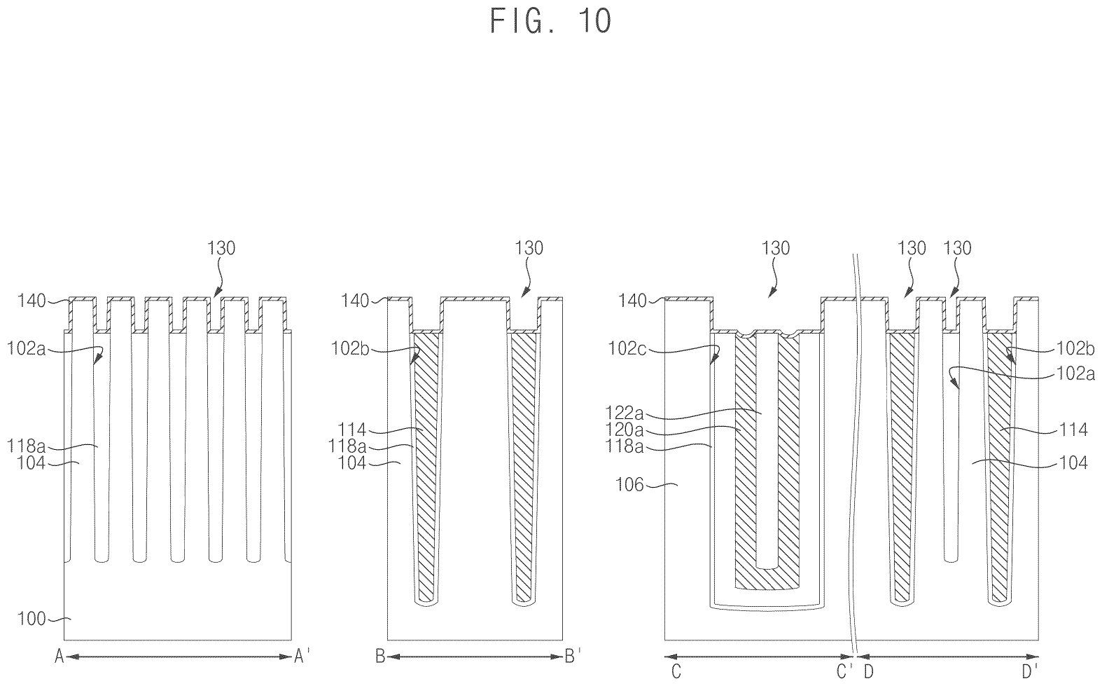

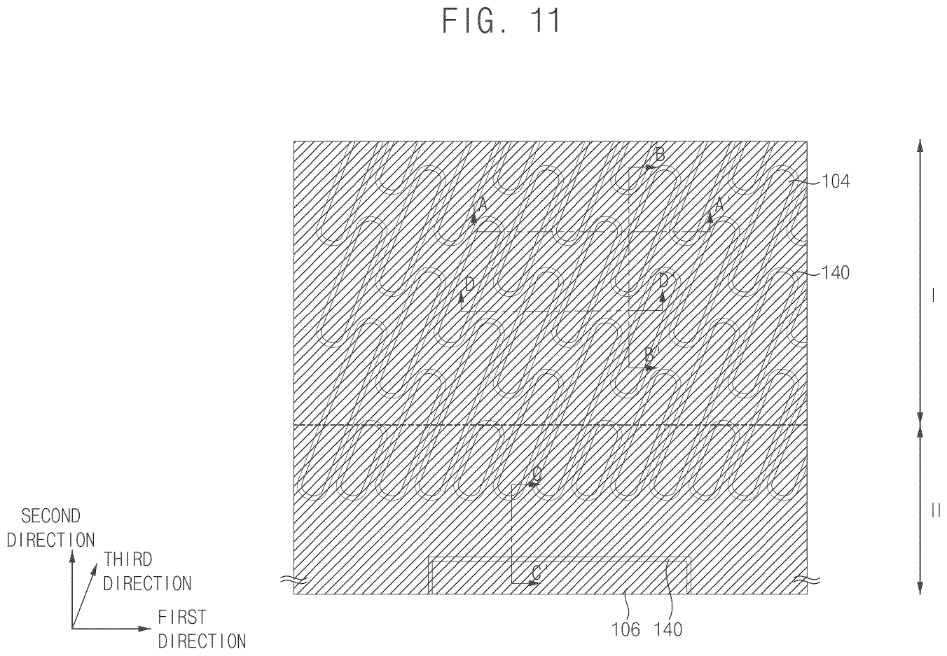

Referring to FIGS. 10 and 11, an upper silicon layer 140 may be conformally formed on the upper surfaces and upper sidewalls of the first active pattern 104 and the second active pattern 106, and surfaces of the first filling insulation layer pattern 118a, the second insulation layer pattern 114 and the second and third filling insulation layer patterns 120a and 122a exposed by the bottom of the first recess.

The upper silicon layer 140 may be formed so as to define a space inside the first recess 130, after forming the upper silicon layer 140. In a deposition process of the upper silicon layer 140, the upper silicon layers 140 on the sidewalls of the first recess 130 may not contact to each other.

The upper silicon layer 140 may be formed on the upper surfaces of the first and second active patterns 104 and 106, and may not be formed on lower sidewalls of the first and second active patterns 104 and 106. Therefore, compared to a case that the silicon layer may be formed on the upper surface, entire sidewall of the first active pattern 104 and a bottom, a stress of the first active pattern 104 due to the upper silicon layer may be small. When the upper silicon layer 140 is formed, a defect in which the first active pattern 104 is bent due to the stress may not occur or be reduced.

In example embodiments, the upper silicon layer 140 may include polysilicon. The upper silicon layer 140 may be formed by for example, a chemical vapor deposition process or an atomic layer deposition process or the like.

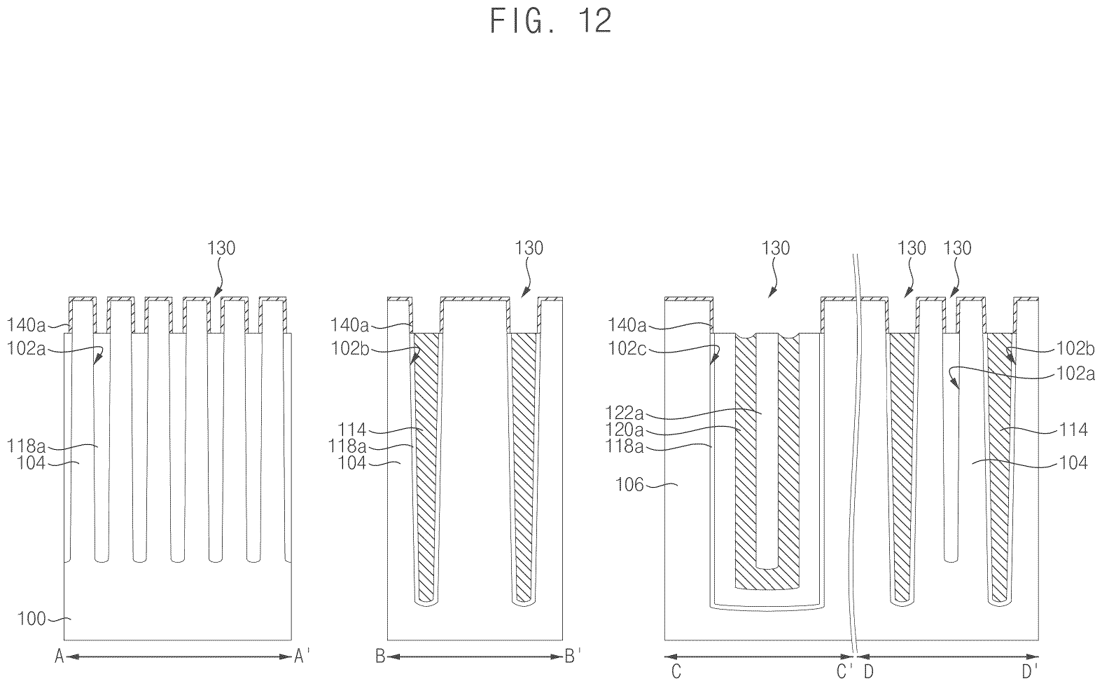

In some example embodiments, the upper silicon layer may be formed by a selective epitaxial growth process or the like. In this case, as shown in FIG. 12, the upper silicon layer may be formed only on exposed upper surfaces and upper sidewalls of the first active pattern 104 and the second active pattern 106. The upper silicon layer may not be formed on the surfaces of the first filling insulation layer pattern 118a, the second insulation layer pattern 114, and the second and third filling insulation layer patterns 120a and 122a on the bottom of the first recess 130. The upper silicon layer may include, for example, single crystal silicon.

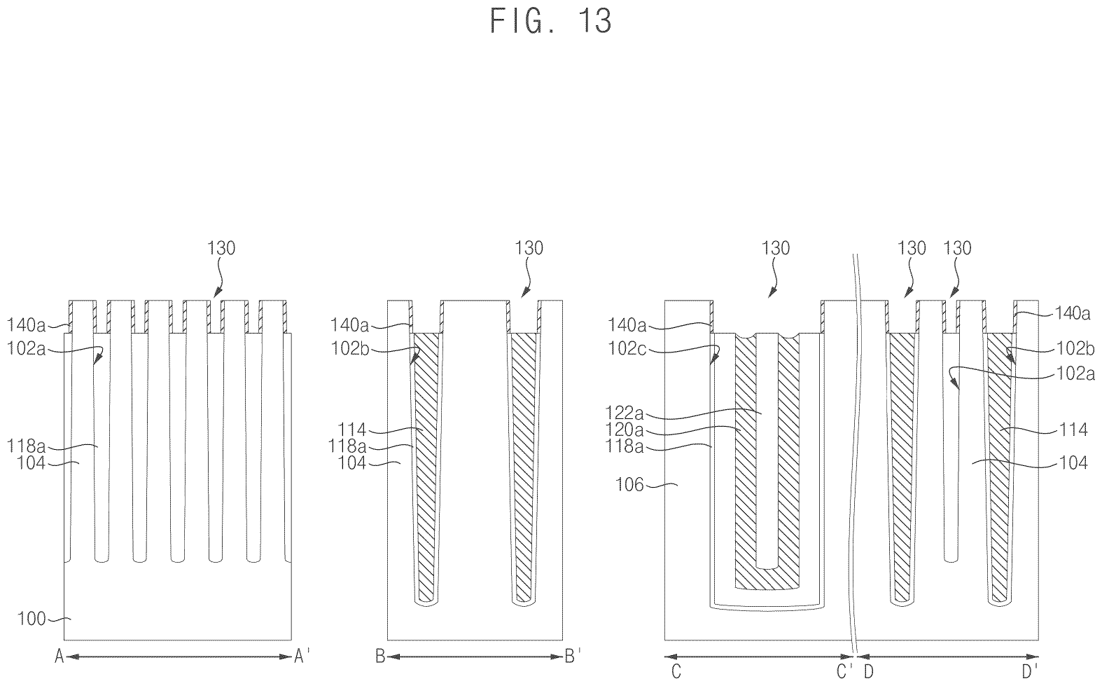

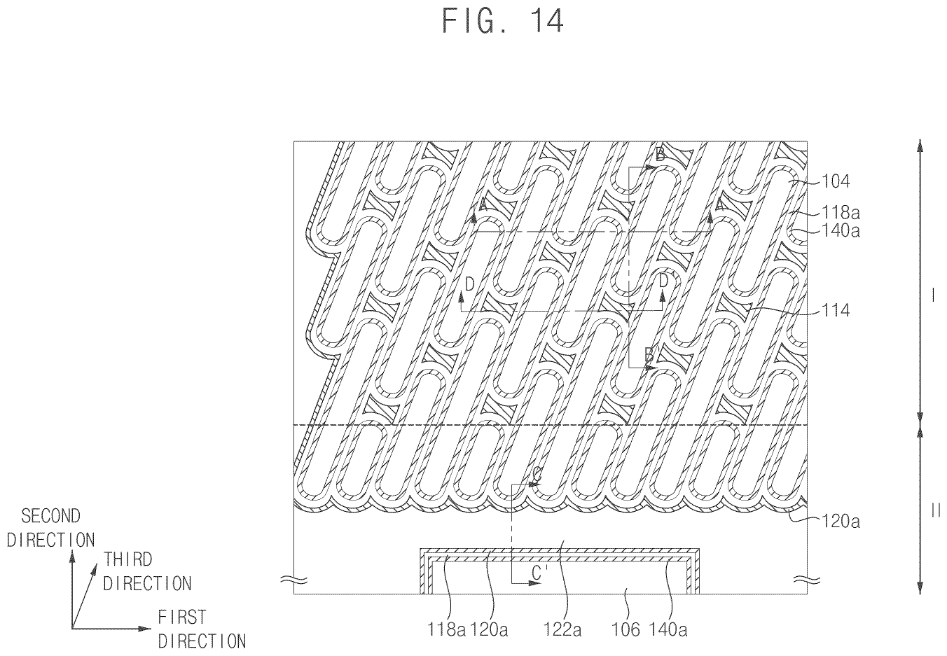

Referring to FIGS. 13 and 14, the upper silicon layer 140 may be anisotropically etched to form an upper silicon pattern 140a covering the upper sidewalls of the first and second active patterns 104 and 106.

The upper silicon layer 140 on the upper surfaces of the first and second active patterns 104 and 106 and on the bottom of the first recess 130 may be removed by the etching process.

The upper silicon pattern 140a may be formed on the sidewall of the first recess 130. The upper silicon pattern 140a may surround upper sidewalls of the first and second active patterns 106. The upper silicon pattern 140a may serve as an active region together with the first and second active patterns 104 and 106. The first active pattern 104 and the upper silicon pattern 140a contacting the first active pattern 104, and the second active pattern 106 and the upper silicon pattern 140a contacting the second active pattern 106 may serve as an effective active region, so that the effective active region may be increased.

When the upper silicon layer 140 is formed by the selective epitaxial growth process, the upper silicon layer may not be formed on the bottom of the first recess 130. Therefore, the anisotropic etching process of the upper silicon layer may be omitted. In this case, the upper silicon pattern 140a may be formed on the upper surface and upper sidewalls of the first and second active patterns 104 and 106.

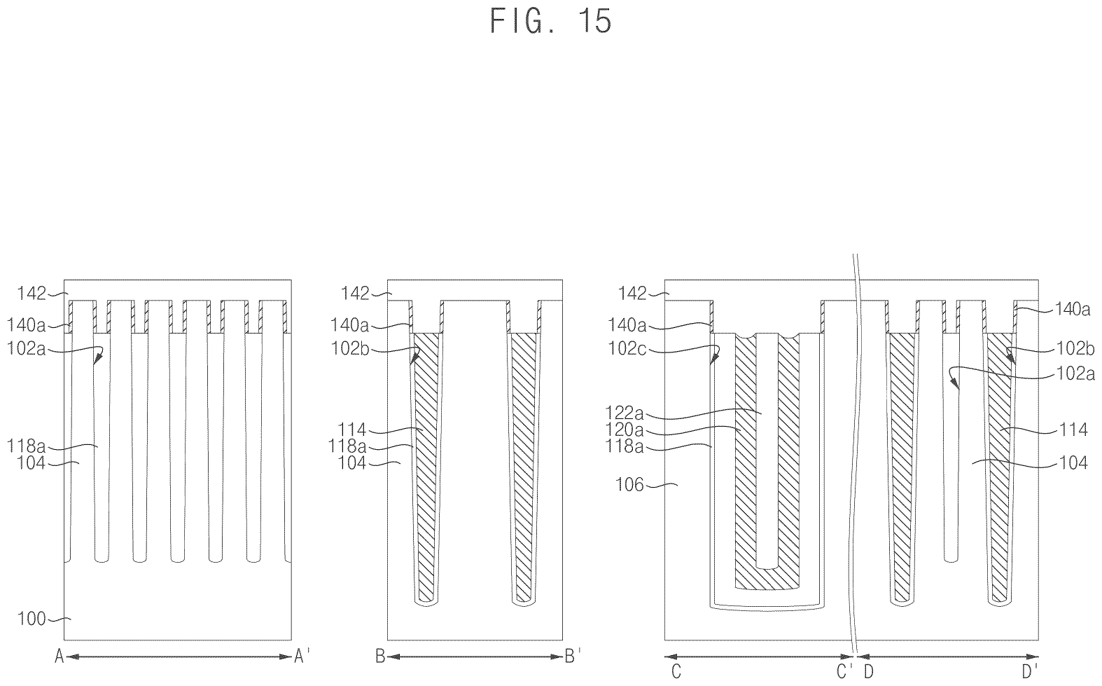

Referring to FIG. 15, a first capping insulation layer 142 may be formed on the first and second active patterns 104 and 106, an upper silicon pattern 140a, a first filling insulation layer pattern 118a, a second insulation layer pattern 114 and the second and third filling insulation layer patterns 120a and 122a to fill the first recess 130. The first capping insulation layer 142 may include, for example, silicon oxide. In example embodiments, after forming the first capping insulation layer 142, a planarization process of an upper surface of the first capping insulation layer 142 may be further performed. The planarization process may include, for example, a chemical mechanical polishing process or the like.

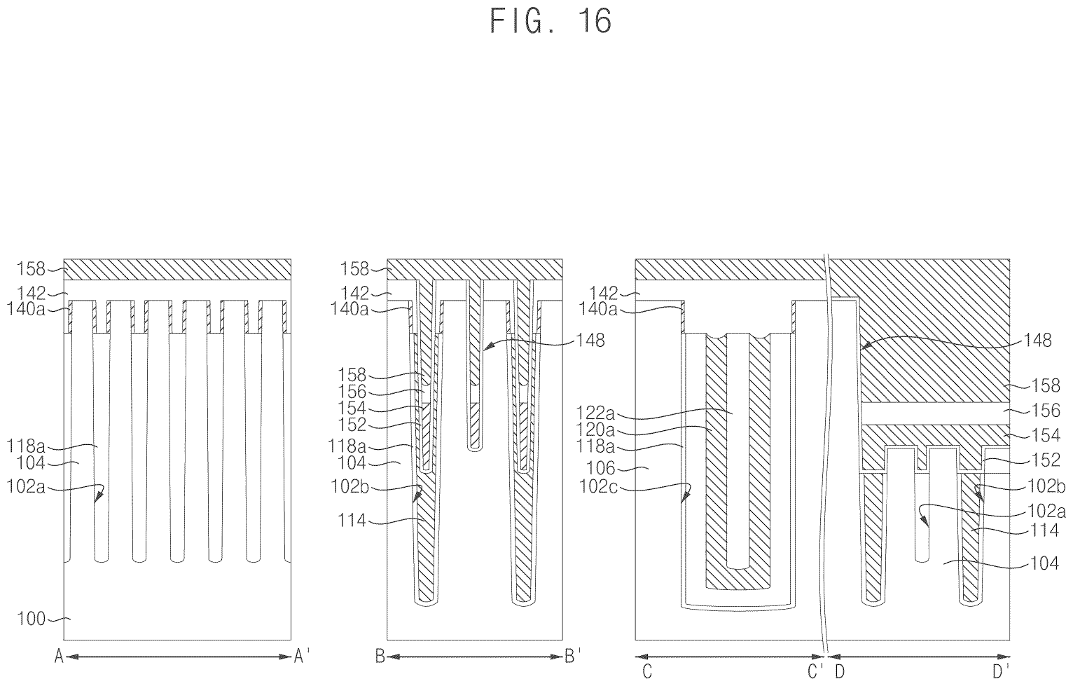

Referring to FIG. 16, a second mask pattern may be formed on the first capping insulation layer 142. The first capping insulation layer 142, the first active pattern 104, the upper silicon pattern 140a, the first filling insulation layer pattern and the second insulation layer pattern 114 on the first region I may be etched using the second mask pattern as an etching mask to form gate trenches 148 for forming gate structures. The gate trenches 148 may extend in the first direction, and the gate trenches 148 may be spaced apart from each other in the second direction. Two spaced gate trenches 148 may be formed on each of the first active patterns 104.

In example embodiments, the upper silicon pattern 140a overlapping the gate trench 148 may be completely etched. A bottom of the gate trench 148 may be lower than a bottom of the upper silicon pattern 140a.

In example embodiments, both sidewalls of the gate trench 148 formed in the second trench 102b and the upper silicon pattern 140a may be spaced apart from each other. The upper silicon pattern 140a may not be exposed by the both sidewalls of the gate trench 148 formed in the second trench 102b.

A gate insulation layer 152 may be conformally formed on an inner surface of the gate trench 148, and a gate electrode layer may be formed on the gate insulation layer 152 to fill the gate trench 148. Thereafter, the gate electrode layer may be etch-backed to form a gate electrode 154 at a lower portion of the gate trench 148. The gate electrode 154 may include a barrier pattern and a metal pattern. A first polysilicon pattern 156 may be further formed on the gate electrode 154.

Thereafter, a second capping insulation layer 158 may be formed on the first capping insulation layer 142 and the first polysilicon pattern 156 to completely fill the gate trench 148. The second capping insulation layer 158 may include, for example, silicon nitride.

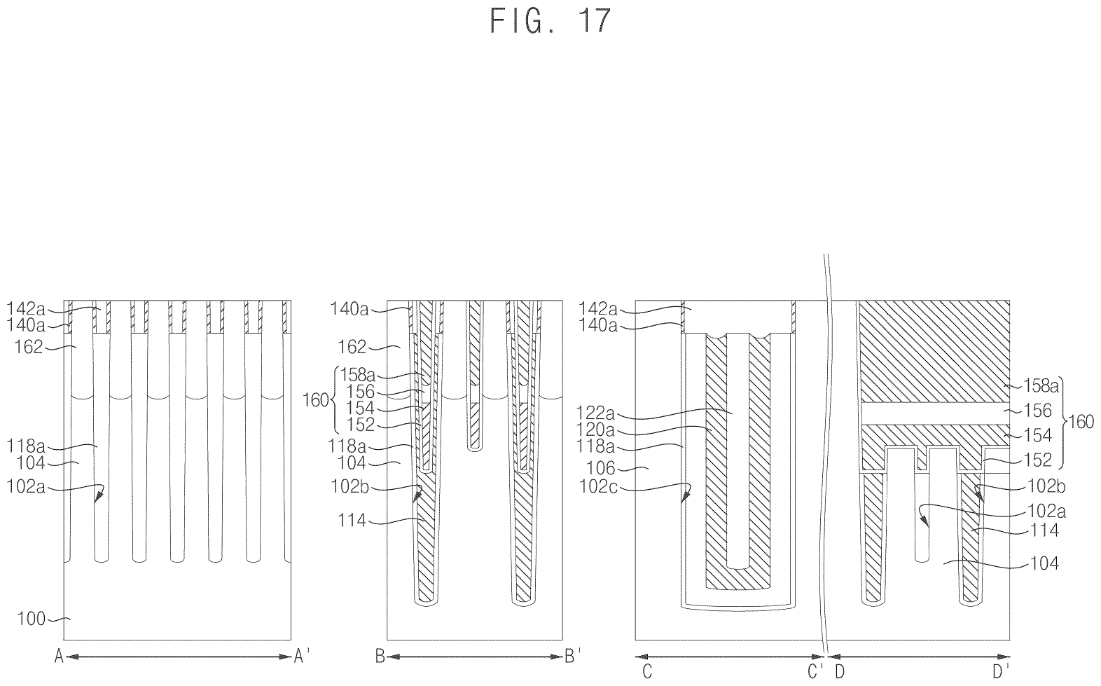

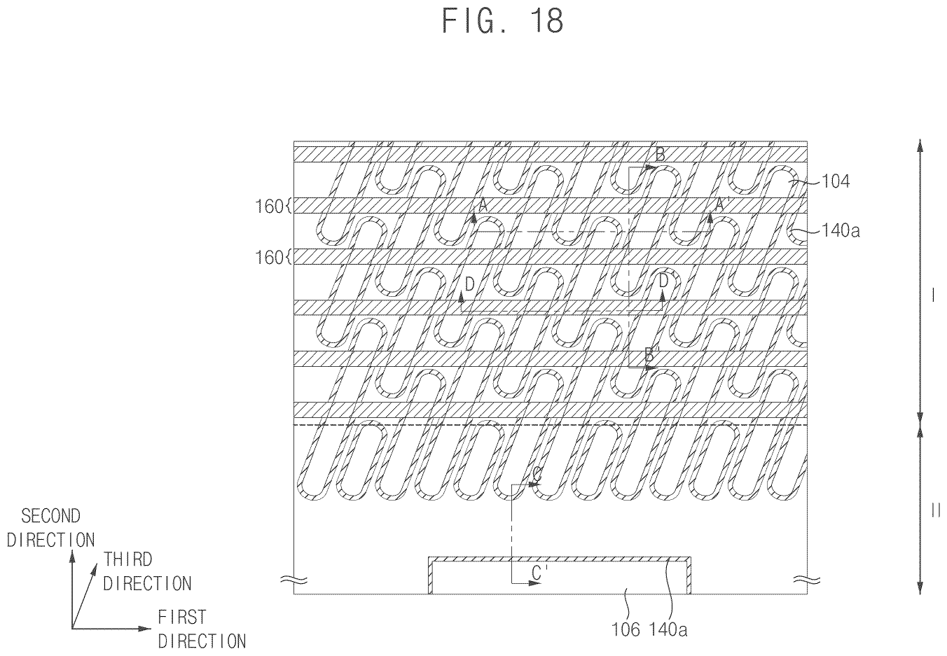

Referring to FIGS. 17 and 18, a portion of the second capping insulation layer 158 may be etched by etch back process, so that the second capping insulation layer 158 may remain in the gate trench 148. Accordingly, the second capping layer pattern 158a may be formed in the gate trench 148. An upper surface of the second capping layer pattern 158a may have a vertical level the same or substantially the same as a vertical level of the upper surface of the first active pattern 104.

By performing the above processes, a gate structure 160 including the gate insulation layer 152, the gate electrode 154, the first polysilicon pattern 156, and the second capping layer pattern 158a may be formed in the gate trench 148.

The upper portion of the first capping insulation layer 142 may be removed so as to expose the upper surfaces of the first and second active patterns 104 and 106 and the upper silicon pattern 140a. The removing process of the upper portion of the first capping insulation layer 142 may include, for example, chemical mechanical polishing process and/or an etch-back process. When the above process is performed, a first capping insulation pattern 142a may be formed in the first recess 130.

Thereafter, impurities may be doped at the upper surfaces of the first active pattern 104 and the upper silicon pattern 140a to form an impurity region 162 serving as a source/drain region. In example embodiments, a bottom of the impurity region 162 may overlap a sidewall of the first polysilicon pattern 156 included in the gate structure 160.

In some example embodiments, the process for forming the impurity region 162 may be performed before forming the first to third trenches 102a, 102b, and 102c for the device isolation, or before forming the gate trench 148.

As shown in FIGS. 17 and 18, the upper silicon pattern 140a may remain on an upper outer wall of the first active pattern 104 on the first region I where the gate structure 160 is not formed. A portion of the first active pattern 104 between the gate structures 160 may be a portion where a contact plug is formed by a subsequent process.

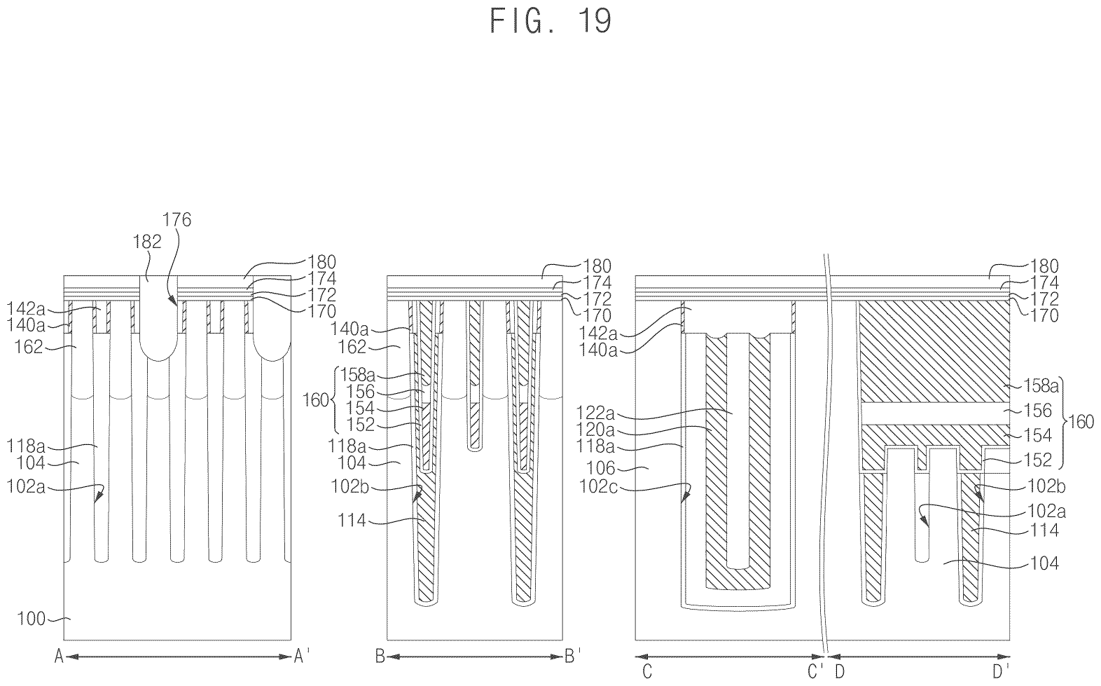

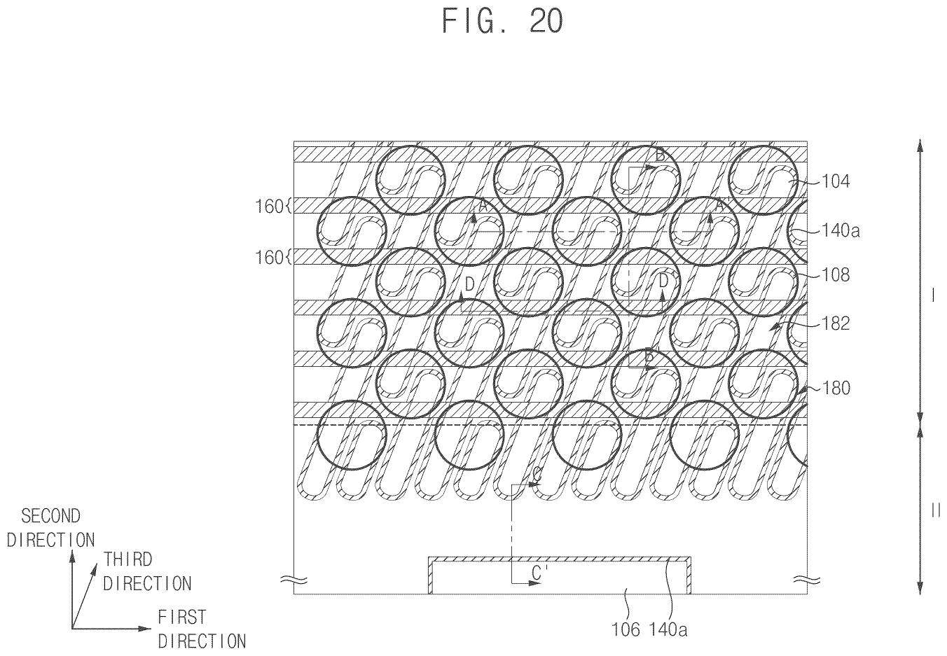

Referring to FIGS. 19 and 20, a first buffer insulation layer 170, a second buffer insulation layer 172, and a third buffer insulation layer 174 may be sequentially formed on the first region I and the second region II of the substrate 100.

The first buffer insulation layer 170 and the third buffer insulation layer 174 may include, for example, silicon oxide. The second buffer insulation layer 172 may include, for example, silicon nitride. Each of the first to third buffer insulation layers 170, 172, and 174 may be formed by an atomic layer deposition process or the like.

A first conductive layer 180 may be formed on the third buffer insulation layer 174. A third mask pattern may be formed on the first conductive layer 180. The first conductive layer 180, the third buffer insulation layer 174, the second buffer insulation layer 172, and the first buffer insulation layer 170 may be partially etched using the third mask pattern as an etching mask to form a first opening 176 exposing an upper portion of the first active pattern 104. In example embodiments, the first opening 176 may be disposed between the gate structures 160, and may expose a central portion of the upper surface of each of the first active patterns 104.

An upper portion of the first active pattern 104 and the upper silicon pattern 140a exposed by the first opening 176, and the first filling insulation layer pattern 118a adjacent thereto may be partially removed by the etching process. In example embodiments, the upper surface of the first active pattern 104 exposed by the first opening 176 may be lower than the bottom of the upper silicon pattern 140a. Accordingly, the upper silicon pattern 140a on both sidewalls of the central portion of the first active pattern 104 exposed by the first opening 176 may be removed.

A bottom of the first opening 176 may be higher than the bottom of the impurity region 162.

A second conductive layer 182 may be formed to fill the first opening 176.

In example embodiments, after forming a preliminary second conductive layer to fill the first opening 176, an upper portion of the preliminary second conductive layer may be etched by an etch back process. Accordingly, an upper surface of the second conductive layer 182 may be coplanar with an upper surface of the first conductive layer 180.

The first and second conductive layers 180 and 182 may include, for example, polysilicon doped with impurities, and thus the first and second conductive layers 180 and 182 may be merged with each other.

Thereafter, the third mask pattern may be removed.

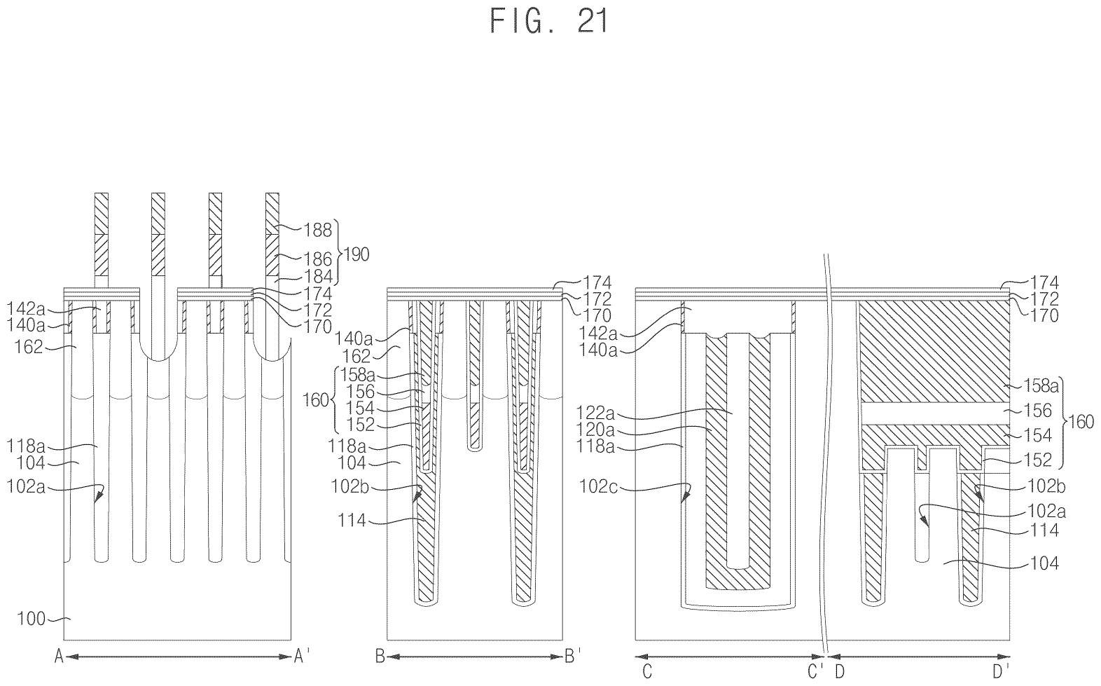

Referring to FIG. 21, a barrier layer, a first metal layer, and a third capping insulation layer may be sequentially formed on the first and second conductive layers 180 and 182. The third capping insulation layer may include silicon nitride.

The third capping insulation layer may be etched to form a third capping insulation pattern 188. The first metal layer, the barrier layer, and the first and second conductive layers 180 and 182 may be sequentially etched using the third capping insulation pattern 188 as an etch mask.

Accordingly, a second conductive pattern, a barrier pattern, a first metal pattern 186, and a third capping insulation pattern 188 may be sequentially stacked on the first active pattern 104 in the first opening 176. A first conductive pattern, the barrier pattern, the first metal pattern 186, and the third capping insulation pattern 188 may be sequentially stacked on the third buffer insulation layer 174 outside the first opening 176.

As described above, the first and second conductive layers 180 and 182 may be merged with each other, and thus the first and second conductive patterns may serve as a conductive pattern 184. A stacked structure including the conductive pattern 184, barrier pattern, first metal pattern 186, and third capping insulation pattern 188 may serve as the bit line structure 190.

In example embodiments, the bit line structures 190 may extend in the second direction, and the bit line structures 190 may be spaced apart from each other in the first direction. The bit line structure 190 may extend in the second direction while contacting the surface of the first active pattern 104 exposed by the bottom of the first openings 176.

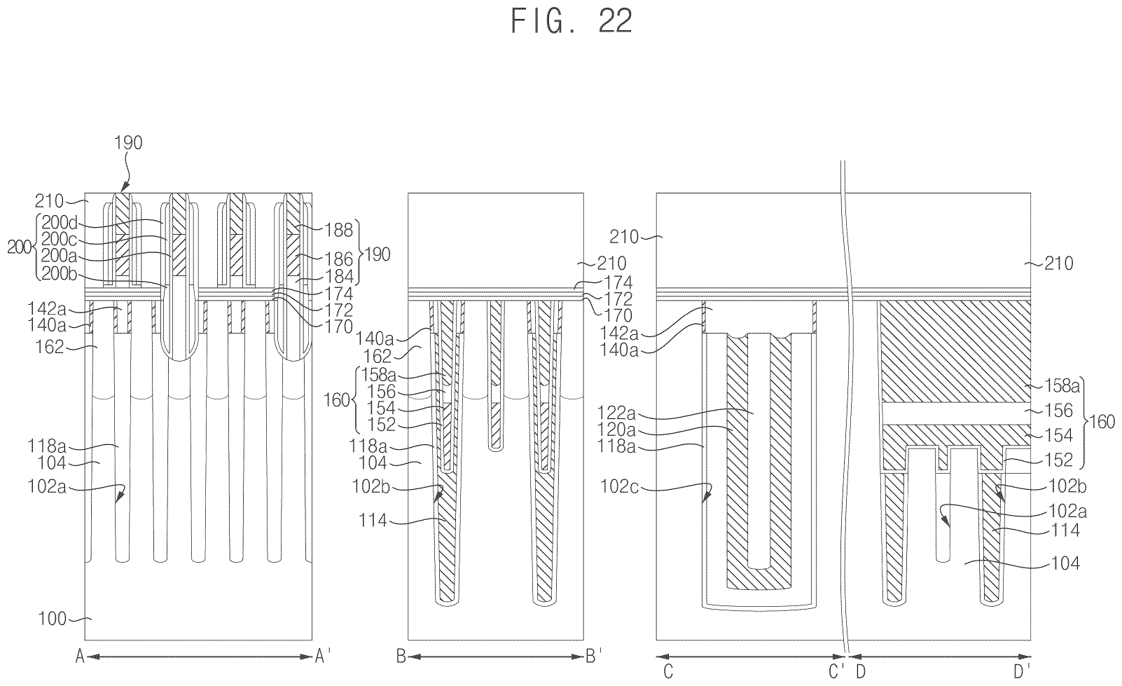

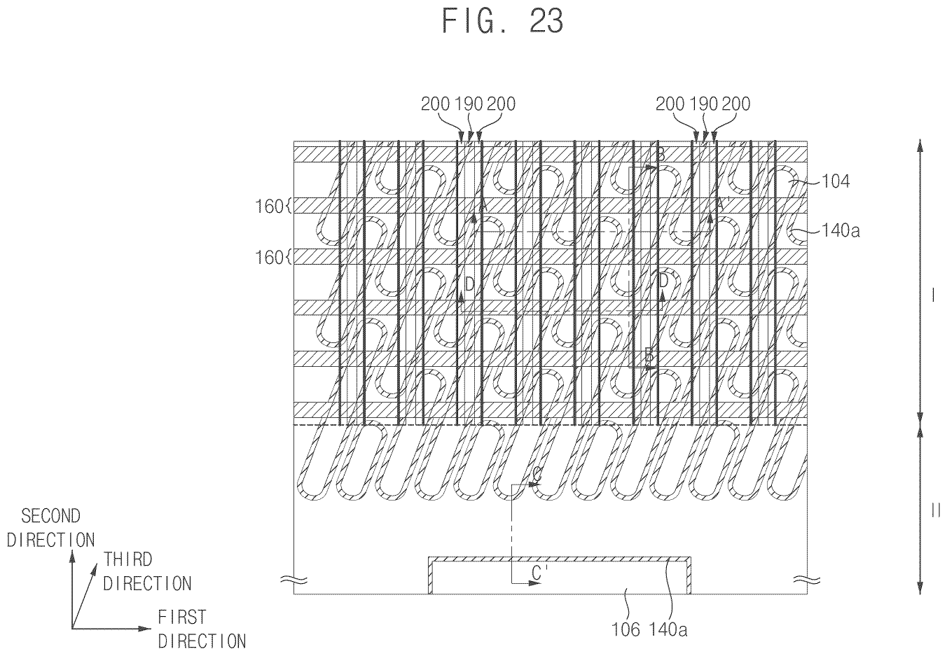

Referring to FIGS. 22 and 23, a spacer structure 200 may be formed to cover a sidewall of the bit line structure 190. The spacer structure 200 may include a plurality of spacers stacked in a lateral direction from the sidewall of the bit line structure 190. The spacers may include, for example, insulation materials.

In example embodiments, the spacer structure 200 may include a first spacer 200a covering the sidewall of the bit line structure 190, a second spacer 200b filling the first opening 176, and third and fourth spacers 200c and 200d covering the sidewalls of the bit line structure 190 and sequentially stacked on the first spacer 200a. In some example embodiments, at least one of the spacers included in the spacer structure 200 may be an air spacer (for example, filed with atmosphere, non-reactive gas, or the like) or an empty space (for example, a vacuum) defined by adjacent spacers and/or layers.

Thereafter, a first insulating interlayer 210 may be formed on the third buffer insulation layer 174 to fill a gap between the spacer structures 200. An upper surface of the first insulating interlayer 210 may be planarized until an upper surface of the spacer structure 200 is exposed. The first insulating interlayer 210 may include, for example, silicon oxide.

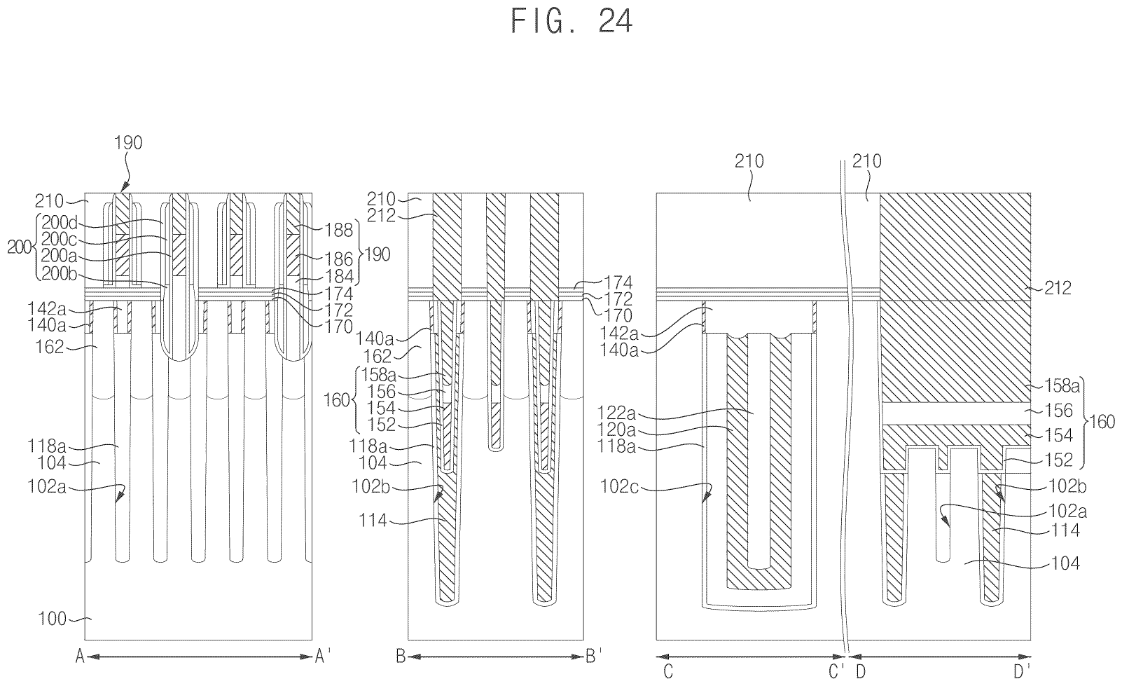

Referring to FIG. 24, after forming a fourth mask pattern on the first insulating interlayer 210 and the spacer structure 200, the first insulating interlayer 210 and the first to third buffer insulation layers 170, 172, and 174 may be etched using the fourth mask pattern as an etching mask to form a second opening.

In example embodiments, the fourth mask pattern may extend in the first direction. A plurality of fourth mask patterns may be spaced apart from each other in the second direction. The second opening may overlap the gate structure 160. An upper surface of the gate structure 160 may be exposed by a bottom of the second opening.

Thereafter, a fence insulation pattern 212 may be formed to fill the second opening. The fence insulation pattern 212 may include nitride, such as silicon nitride. The fence insulation pattern 212 may overlap the gate structure 160, for example, may be vertically over the gate structure 160. In some example embodiments, the fence insulation pattern 212 may have a same width in the second direction as the gate structure 160 at a level the fence insulation pattern 212 and the gate structure 160 meet.

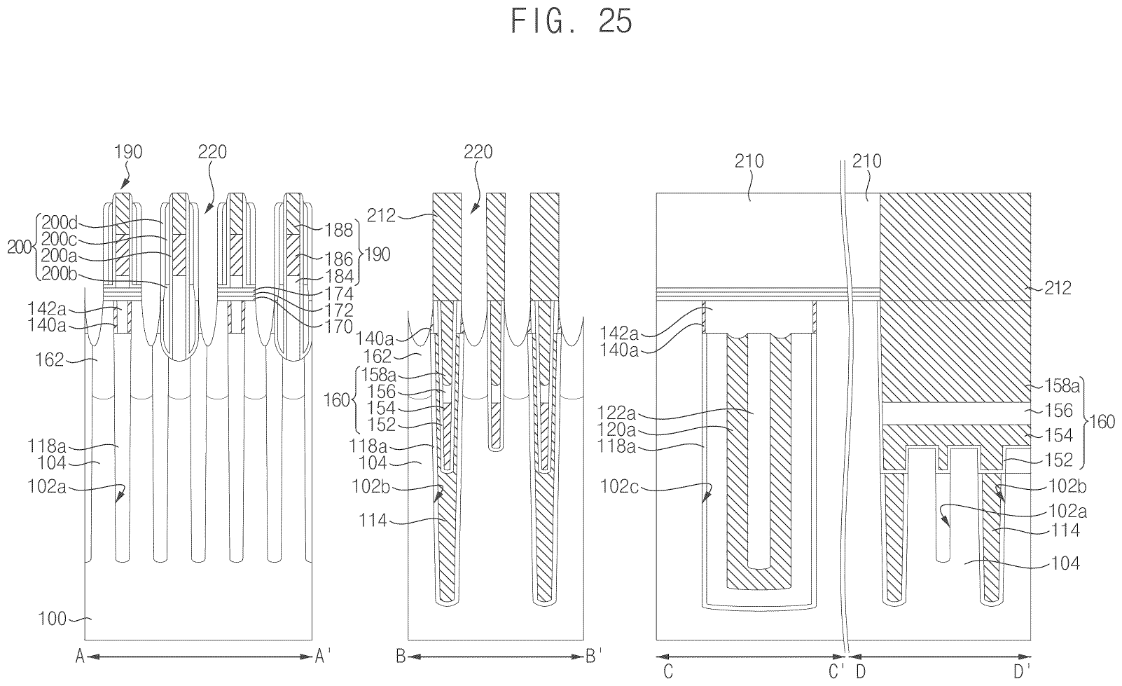

Referring to FIGS. 25 to 27, the first insulating interlayer 210 may be etched, and then the third buffer insulation layer 174, the second buffer insulation layer 172, and the first buffer insulation layers 170 and upper portions of the first active pattern 104 and the upper silicon pattern below the first insulating interlayer 210 may be sequentially etched to form the third opening 220.

The third opening 220 may expose an edge portion in the third direction of the first active pattern 104 positioned at a space defined by the fence insulation pattern 212 and the bit line structure 190. In the etching process, an upper portion of the first filling insulation layer pattern 118a adjacent to the upper portion of the first active pattern 104 may be additionally and partially etched.

A bottom of the third opening 220 may be lower than the bottom of the upper silicon pattern 140a.

A portion of the third opening 220 lower than the bottom of the first buffer insulation layer 170 may be referred to as a lower portion. In a cross-sectional view, the lower portion of the third opening 220 may have a rounded shape. Additionally, the upper silicon pattern 140a may be exposed by a lower sidewall of the third opening 220.

Since the upper silicon pattern 140a is formed on an upper sidewall of the first active pattern 104, a horizontal area of the effective active region may be increased. The upper portion of the first active pattern 104 and the upper silicon pattern 140a may be etched to form the lower portion of the third opening 220. Therefore, as shown in FIG. 27, the first active pattern 104 and the upper silicon pattern 140a may be exposed on the sidewall of the third opening 220. The upper silicon pattern 140a may be additionally exposed by the sidewall of the third opening 220, so that the horizontal area of the effective active region may be increased.

If the upper silicon pattern 140a may not be formed on the first active pattern 104, only the first active pattern 104 may be exposed by the third opening 220. Since the upper silicon pattern 140a is not exposed by the bottom of the third opening 220, the surface of the effective active region exposed by the third opening 220 may be relatively small, compared to a case where the upper silicon pattern 140a is further formed.

After performing the etching process, the upper silicon pattern 140a may remain on an upper sidewall of the edge portion in the third direction of the first active pattern 104. The upper silicon pattern 140a may remain on the upper sidewall of the first active pattern 104 disposed outside of the third opening 220 from an outer wall of the gate structure 160. The upper silicon pattern 140a on the upper sidewall adjacent to the central portion in the third direction of the first active pattern 104 may be removed, and may not be remain.

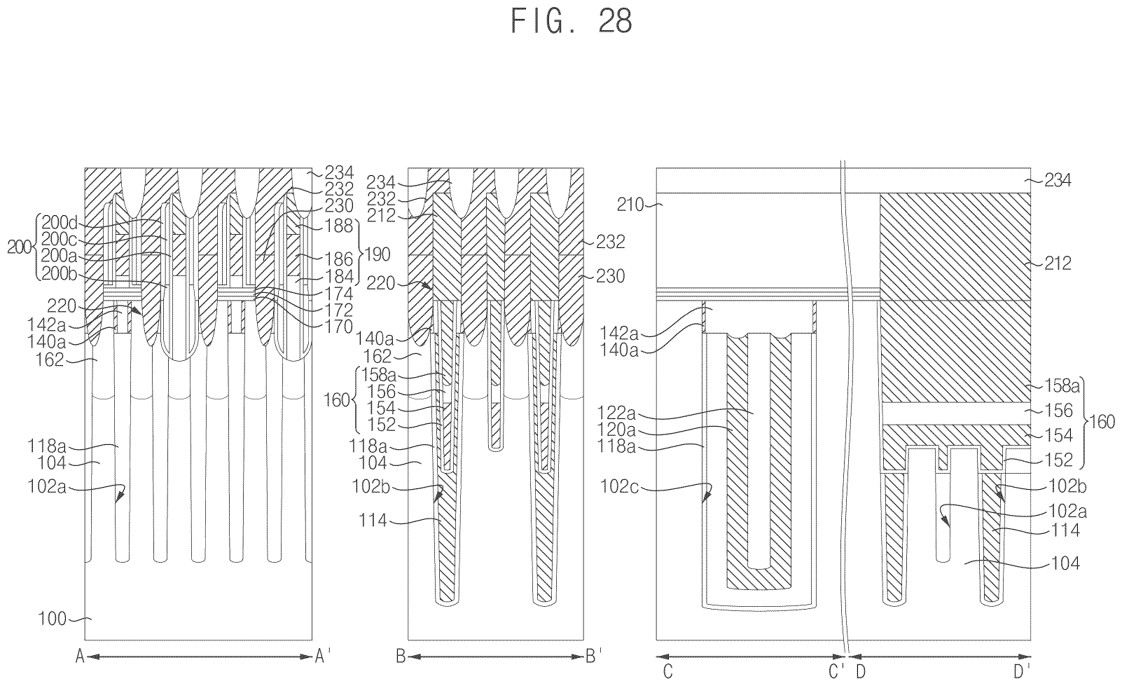

Referring to FIG. 28, a first contact plug 230 may be formed to fill at least a portion of the third opening 220. The first contact plug 230 may include, for example, polysilicon.

The first contact plug 230 may contact the first active pattern 104 and the upper silicon pattern 140a. As the upper silicon pattern 140a is formed on the upper sidewall of the first active pattern 104, a contact area between the first contact plug 230 and the active region may be increased. Accordingly, a contact resistance between the first contact plug 230 and the active region may be decreased.

A landing pad pattern 232 may be formed on the first contact plug 230, and may contact the first contact plug 230. An upper surface of the landing pad pattern 232 may be higher than an upper surface of the bit line structure 190.

The landing pad pattern 232 may include metals, for example, a barrier metal and a metal. An upper insulation pattern 234 may be formed to fill a space between the landing pad patterns 232.

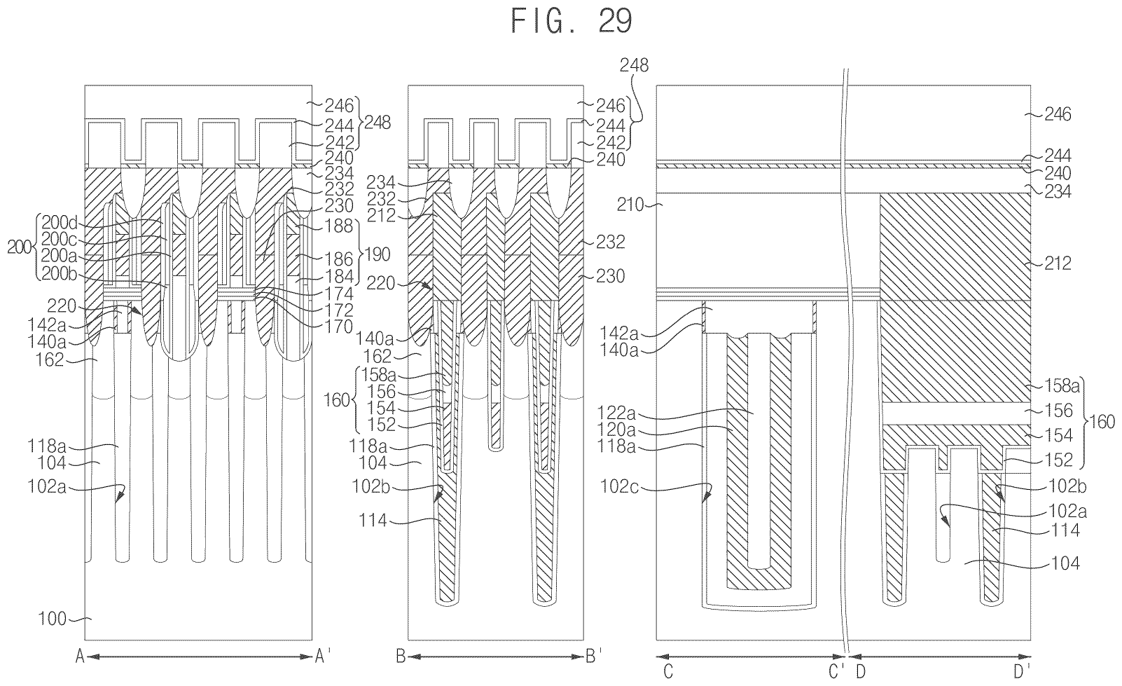

Referring to FIG. 29, an etch stop layer 240 may be formed on the landing pad pattern 232 and the upper insulation pattern 234. A capacitor 248 may be formed on the landing pad pattern 232 through the etch stop layer 240. The capacitor 248 may include a lower electrode 242, a dielectric layer 244, and an upper electrode 246. The lower electrode 242 of the capacitor 248 may contact the landing pad pattern 232.

By performing the above process, a DRAM device may be manufactured.

The DRAM device may have the following structural characteristics. Most of the structural features of the DRAM device have been described above. Therefore, repeated descriptions may be omitted, and only important parts may be described with reference to the drawings.

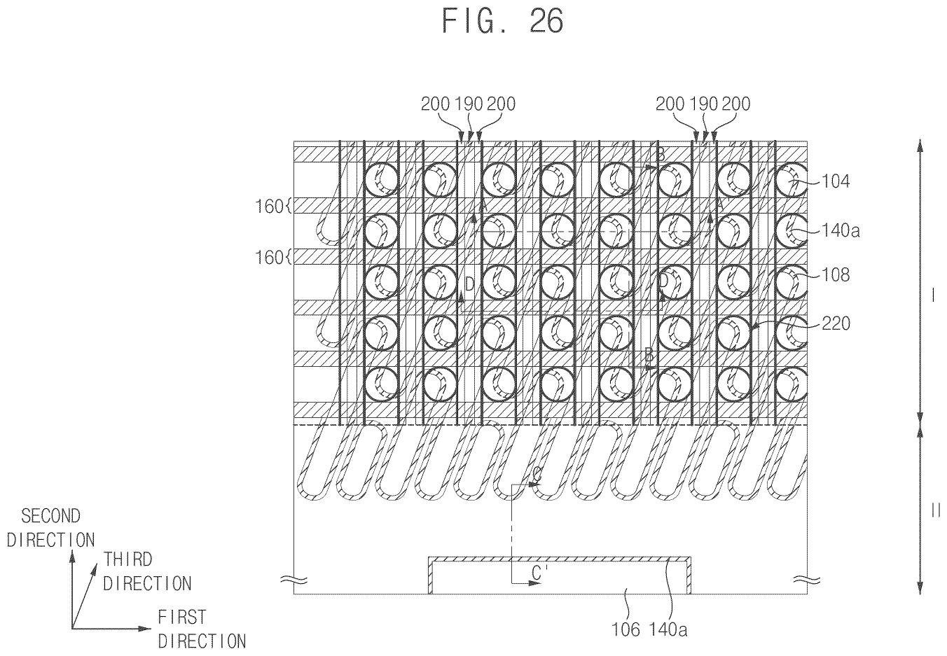

Referring to FIGS. 26, 27, and 29, the substrate 100 on which the semiconductor device is formed may be divided into the first region I and the second region II. The first region I may include the cell region, and the second region II may include the interface region and a core/peripheral region.

The trenches may be formed in the device isolation region of the substrate 100, and the device isolation patterns may fill the trenches. A protruding portion of the substrate 100 between the trenches may be referred to as the active pattern.

The first active patterns 104 may be formed on the first region I of the substrate 100, and the first active patterns 104 may have an isolated shape having the third direction as a longitudinal direction. The first active patterns 104 may be regularly arranged in each of the first direction and the second direction.

In example embodiments, the cell trenches and the first active pattern 104 may be formed on the first region I. The cell trench may include the first trench 102a having the narrowest first width and the second trench 102b having the second width greater than the first width.

The third trench 102c and the second active pattern 106 may be formed on the second region II. The third trench 102c may have a width greater than each of the first and second trenches 102a and 102b.

The first filling insulation layer pattern 118a may fill the first trench 102a. The first filling insulation layer pattern 118a and the second insulation layer pattern 114 may fill the second trench 102b. The first filling insulation layer pattern 118a, the second filling insulation layer pattern 120a, and the third filling insulation layer pattern 122a may fill the third trench 102c.

The first filling insulation layer pattern 118a may include, for example, silicon oxide. The second insulation layer pattern 114 may include, for example, silicon nitride. The second filling insulation layer pattern 120a may include, for example, silicon nitride. The third filling insulation layer pattern 122a may include, for example, silicon oxide.

Upper surfaces of the first filling insulation layer pattern 118a, the second insulation layer pattern 114, and the second and third filling insulation layer patterns 120a, 122a filling the first to third trenches 102a, 102b, and 102c may be lower than an uppermost surface of the substrate 100. Therefore, an uppermost surface of the device isolation pattern filling each of the first to third trenches 102a, 102b, and 102c may be lower than an uppermost surface of the first active pattern 104.

The upper surfaces of the first to third filling insulation layer patterns 118a, 120a, and 122a filling the third trench 102c may not be flat. In example embodiments, as the upper portion of the second filling insulation layer pattern 120a is further etched, an upper surface of the second filling insulation layer pattern 120a may have a recessed portion.

The upper silicon pattern 140a may be formed on an upper sidewall of the first active pattern 104 and an upper sidewall of the second active pattern 106. The upper silicon pattern 140a may be disposed on at least a portion of the sidewall of the first active pattern 104 above the upper surface of the device isolation patterns on the first region I.

The upper silicon pattern 140a may include polysilicon. In some example embodiments, the upper silicon pattern 140a may include single crystal silicon formed by an epitaxial growth process or the like.

The upper silicon pattern 140a may cover at least a portion of the upper sidewall of the first active pattern 104. The upper silicon pattern 140a may cover the upper sidewall of an edge portion in the third direction of the first active pattern 104.

In the first region I, the upper silicon pattern 140a may be disposed on the upper sidewall of the first active pattern 104 disposed outside of the third opening 220 from an outer wall of the gate structure 160. The upper silicon pattern 140a may not be disposed on the upper sidewall of a central portion in the third direction of the first active pattern 104.

Additionally, the upper silicon pattern 140a may cover the upper sidewall of the second active pattern 106. The upper silicon pattern 140a and the first and second active patterns 104 and 106 may serve as the active region together.

The first capping insulation pattern 142a may be between the upper silicon patterns 140a to fill the upper portions of the first to third trenches 102a, 102b, and 102c. The first capping insulation pattern 142a may be disposed on an upper surface of the device isolation pattern. The first capping insulation pattern 142a may contact a sidewall of the upper silicon pattern 140a. An upper surface of the first capping insulation pattern 142a may be coplanar with an uppermost surface of the upper silicon pattern 140a.

The first capping insulation pattern 142a may be formed on the first filling insulation layer pattern 118a filling the first trench 102a. The first capping insulation pattern 142a may be formed on the first filling insulation layer pattern 118a and the second insulation layer pattern 114 filling the second trench 102b. The first capping insulation pattern 142a may be formed on the first to third filling insulation layer patterns 118a, 120a, and 122a filling the third trench 102c. In example embodiments, a bottom of the first capping insulation pattern 142a filling the third trench 102c may not be flat.

The first capping insulation pattern 142a may include, for example, silicon oxide.

The gate trench 148 extending in the first direction may be on the first region of the substrate 100. The gate trench 148 may be disposed on the first active pattern 104 and the device isolation insulation layer. Two gate trenches 148 spaced apart from each other may be disposed on each of the first active patterns 104. A bottom of the gate trench 148 may be lower than a bottom of the upper silicon pattern 140a.

The gate structure 160 may fill the gate trench 148. The gate structure 160 may be disposed on the first region I of the substrate 100. The gate structure 160 may extend in the first direction. The gate structure 160 may include the gate insulation layer 152, the gate electrode 154, the first polysilicon pattern 156, and the second capping insulation pattern 158a.

The impurity region 162 doped with impurities may be at upper portions of the first active pattern 104 and the upper silicon pattern 140a adjacent to both sides of the gate structure 160. In example embodiments, a bottom of the impurity region 162 may overlap the sidewall of the first polysilicon pattern 156 included in the gate structure 160.

The first buffer insulation layer 170, the second buffer insulation layer 172, and the third buffer insulation layer 174 may be sequentially stacked on the first and second regions I and II of the substrate 100. Adjacent buffer insulation layers in the vertical direction may include different insulation materials. In example embodiments, the first buffer insulation layer 170 and the third buffer insulation layer 174 may include, for example, silicon oxide. The second buffer insulation layer 172 may include, for example, silicon nitride.

The first opening 176 may pass through the first to third buffer insulation layers 170, 172, and 174 to expose the upper surface of the first active pattern 104. The first opening 176 may expose a central portion in the third direction of the first active pattern 104. The first opening 176 may be formed by etching an upper portion of the first active pattern 104 and a portion of the device isolation pattern contacting the first active pattern 104. An upper surface of the first active pattern 104 exposed by the bottom of the first opening 176 may be lower than a bottom of the upper silicon pattern 140a. The bottom of the first opening 176 may be higher than a bottom of the impurity region 162.

In the first region I of the substrate 100, the bit line structure 190 may contact the third buffer insulation layer 174 and the upper surface of the first active pattern 104 exposed by the first opening 176. The bit line structure 190 may extend in the second direction while contacting the central portion in the third direction of the first active pattern 104. A bottom of the bit line structure 190 contacting the central portion in the third direction of the first active pattern 104 may be lower than the bottom of the upper silicon pattern 140a.

The bit line structure 190 may include the conductive pattern 184, the barrier pattern, the first metal pattern 186, and the third capping insulation pattern 188 sequentially stacked.

The spacer structure 200 may be on a sidewall of the bit line structure 190.

The fence insulation pattern 212 may be formed on a portion corresponding to the gate structure 160 in a portion between spacer structures 200. The fence insulation pattern 212 may contact an upper surface of the gate structure 160. The fence insulation pattern 212 may contact an upper surface of the second capping insulation pattern 158a. The fence insulation pattern 212 may include, for example, silicon nitride.

The third opening 220 exposing the upper surface of the first active pattern 104 may be formed on a region between the fence insulation pattern 212 and the spacer structure 200. The third opening 220 may expose an edge portion in the third direction of the first active pattern 104. A bottom of the third opening 220 may be lower than the bottom of the upper silicon pattern 140a. The bottom of the first opening 176 may be higher than the bottom of the impurity region 162. In example embodiments, the bottom of the third opening 220 may be higher than the bottom of the first opening 176.

In the cross-sectional view, a lower portion of the third opening 220 may have a rounded shape. Additionally, the upper silicon pattern 140a may be exposed by a lower sidewall of the third opening 220.

The first contact plug 230 may fill a lower portion of the third opening 220. A bottom surface of the first contact plug 230 may be lower than the bottom of the upper silicon pattern 140a. The bottom of the first contact plug 230 may be higher than the bottom of the impurity region 162. In example embodiments, the bottom of the first contact plug 230 may be higher than the bottom of the bit line structure 190 contacting the first active pattern 104.

The first contact plug 230 may contact the first active pattern 104 and the upper silicon pattern 140a disposed between the gate structure 160 and the bit line structure 190. At least a portion of the sidewall of the first contact plug 230 may contact the upper silicon pattern 140a.

As the upper silicon pattern 140a is included in the upper sidewall of the first active pattern 104, a contact region between the first contact plug 230 and the active region may be increased. Accordingly, a contact resistance between the first contact plug 230 and the active region may be decreased. The first contact plug 230 may include, for example, polysilicon.

As described above, the bottom of the bit line structure 190 in the first opening 176 and the bottom of the first contact plug 230 in the third opening 220 may be lower than the bottom of the upper silicon pattern 140a. The bottom of the first active pattern 104 contacting the bit line structure 190 and the bottom of the upper silicon pattern 140a may be spaced apart from each other in the vertical direction, and the bottom of the first active pattern 104 contacting the first contact plug 230 and the bottom of the upper silicon pattern 140a are spaced apart from each other in the vertical direction. Therefore, a variation of interface trap density (NIT) due to the upper silicon pattern 140a may be decreased.

The landing pad pattern 232 may contact an upper surface of the first contact plug 230. An upper surface of the landing pad pattern 232 may be higher than an upper surface of the bit line structure 190. The landing pad pattern 232 may include a metal, for example, a barrier metal and a metal. The upper insulation pattern 234 may fill a space between the landing pad patterns 232.

The etch stop layer 240 may be on upper surfaces of the landing pad pattern 232 and the upper insulation pattern 234. The capacitor 248 may be on the landing pad pattern 232 through the etch stop layer 240.

As described above, the semiconductor device may have the upper silicon pattern on the sidewall of the edge in the third direction of the first active pattern 104. Additionally, a portion of the first contact plug 230 contacting the upper portion of the edge in the third direction of the first active pattern 104 may contact the upper silicon pattern 140a. At least a portion of the sidewall of the first contact plug 230 may contact the upper silicon pattern 140a. Accordingly, a contact region between the first contact plug 230 and the active region may increase, and a contact resistance between the first contact plug 230 and the active region may be decreased.

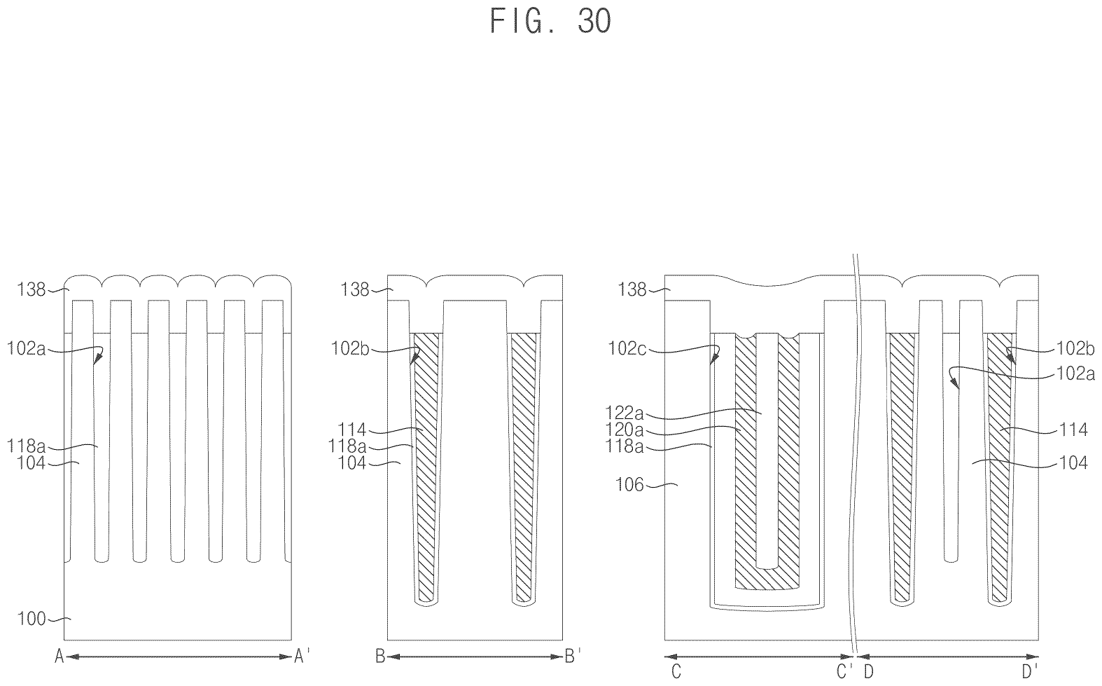

FIGS. 30 to 34 are cross-sectional views illustrating a method for manufacturing a semiconductor device according to example embodiments.

The method for manufacturing the semiconductor device may include the same or similar processes as those described with reference to FIGS. 1 to 29. Therefore, redundant descriptions may be omitted.

Referring to FIG. 30, first, the processes described with reference to FIGS. 1 to 9 may be performed.

Thereafter, a lower capping insulation layer 138 filling the first recesses 130 may be formed on the first and second active patterns 104 and 106 and the device isolation insulation layers. The lower capping insulation layer 138 may include, for example, silicon oxide.

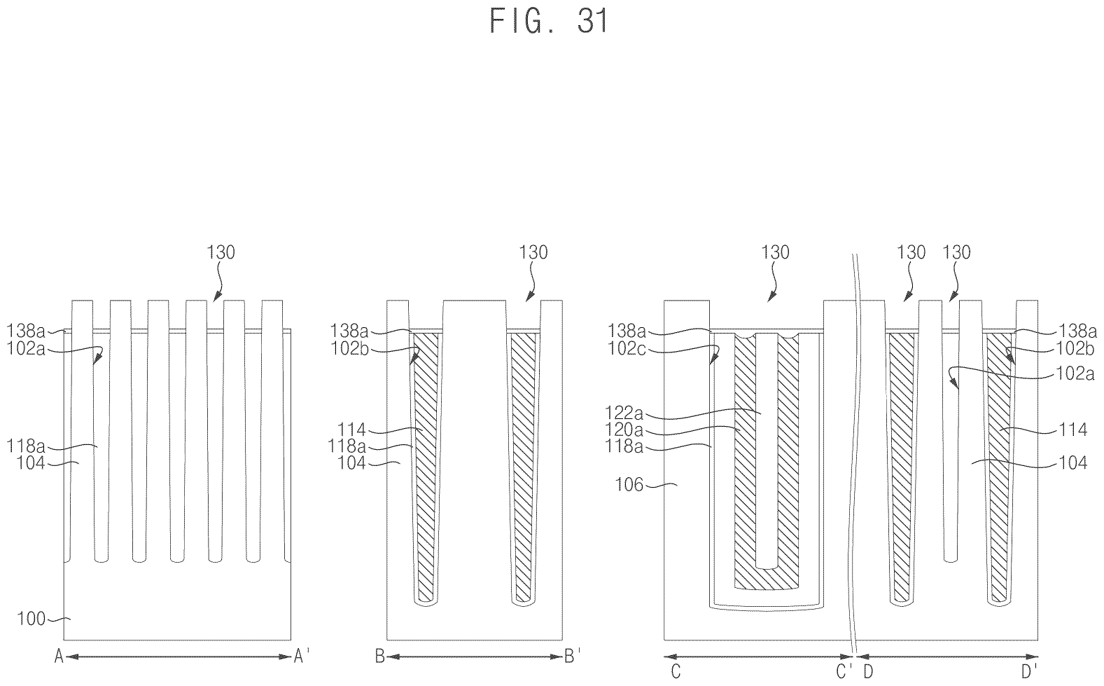

Referring to FIG. 31, an upper surface of the lower capping insulation layer 138 may be planarized until upper surfaces of the first and second active patterns 104 and 106 are exposed.

The planarization process may include, for example, a chemical mechanical polishing process.

Thereafter, an upper portion of the lower capping insulation layer 138 may be etched to expose upper sidewalls of the first and second active patterns 104 and 106 by etch back process. Therefore, a lower capping insulation pattern 138a may be formed.

The lower capping insulation pattern 138a may be provided for a planarization of an upper surface of the device isolation layer filling the third trench 102c. Therefore, the lower capping insulation pattern 138a may cover at least the upper surface of the device isolation insulation layer filling the third trench 102c. Additionally, the upper surface of the lower capping insulation pattern 138a may be flat or substantially flat. The lower capping insulation pattern 138a may also remain on the upper surface of the device isolation layer filling the first and second trenches 102a and 102b.

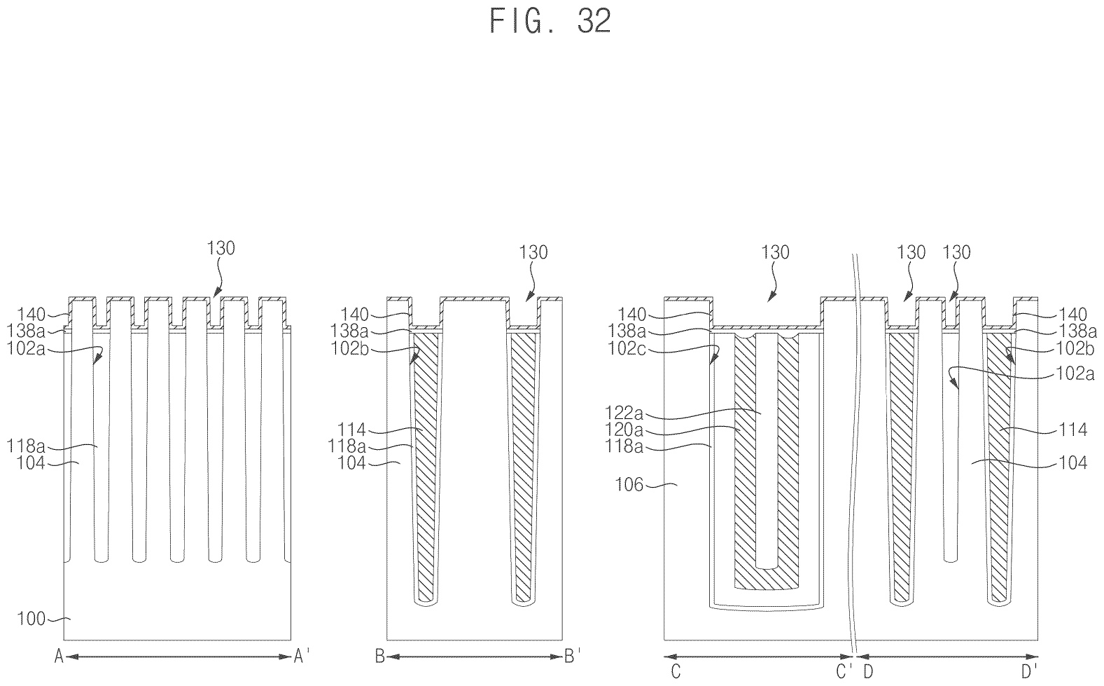

Referring to FIG. 32, an upper silicon layer 140 may be conformally formed on the upper surfaces and upper sidewalls of the first and second active patterns 104 and 106 and the lower capping insulation pattern 138a.

Since the upper surface of the lower capping insulation pattern 138a is flat or substantially flat, an upper surface of the upper silicon layer 140 on the lower capping insulation pattern 138a may be flat or substantially flat.

The process for forming the upper silicon layer 140 may be substantially the same as that described with reference to FIGS. 10 and 11.

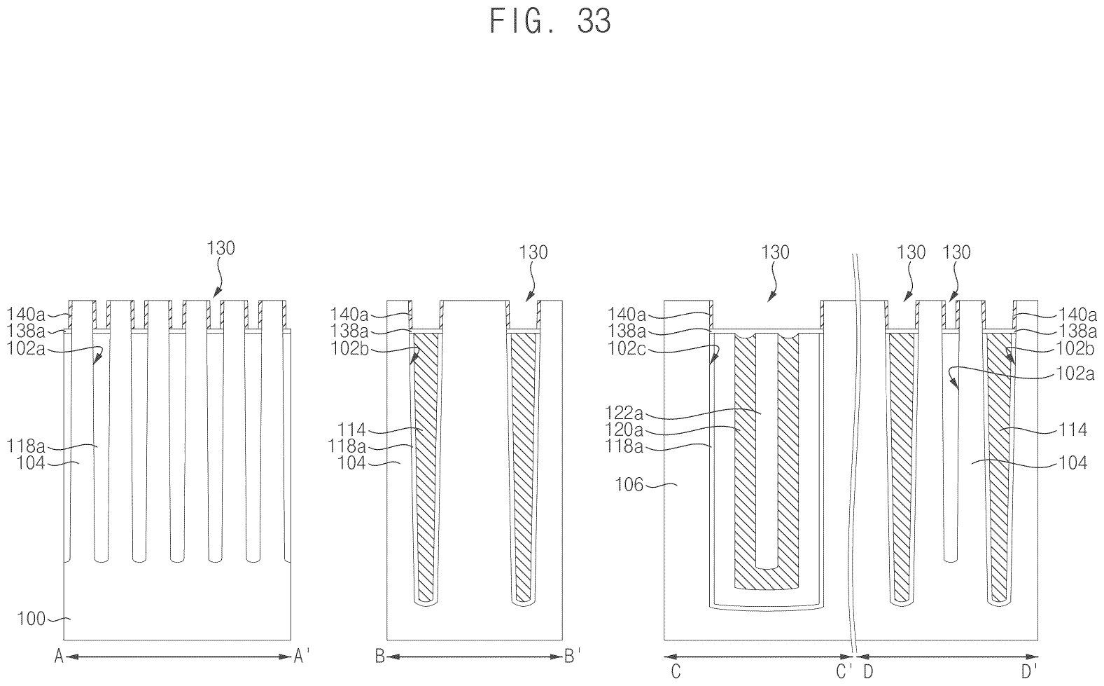

Referring to FIG. 33, the upper silicon layer 140 may be anisotropically etched to form an upper silicon pattern 140a covering upper sidewalls of the first and second active patterns 104 and 106.

When the etching process is performed, the lower capping insulation pattern 138a may be exposed again by a bottom of the first recess 130. Since the upper surface of the lower capping insulation pattern 138a is substantially flat or flat, an upper surface of the upper silicon layer 140 formed thereon may also be flat or substantially flat. Accordingly, the upper silicon layer 140 may be removed by the anisotropic etching process, for example, easily removed at least in part due to the flat or substantially flat surface. Therefore, defects in which the upper silicon layer 140 on a bottom of the first recess 130 may not be removed may be decreased.

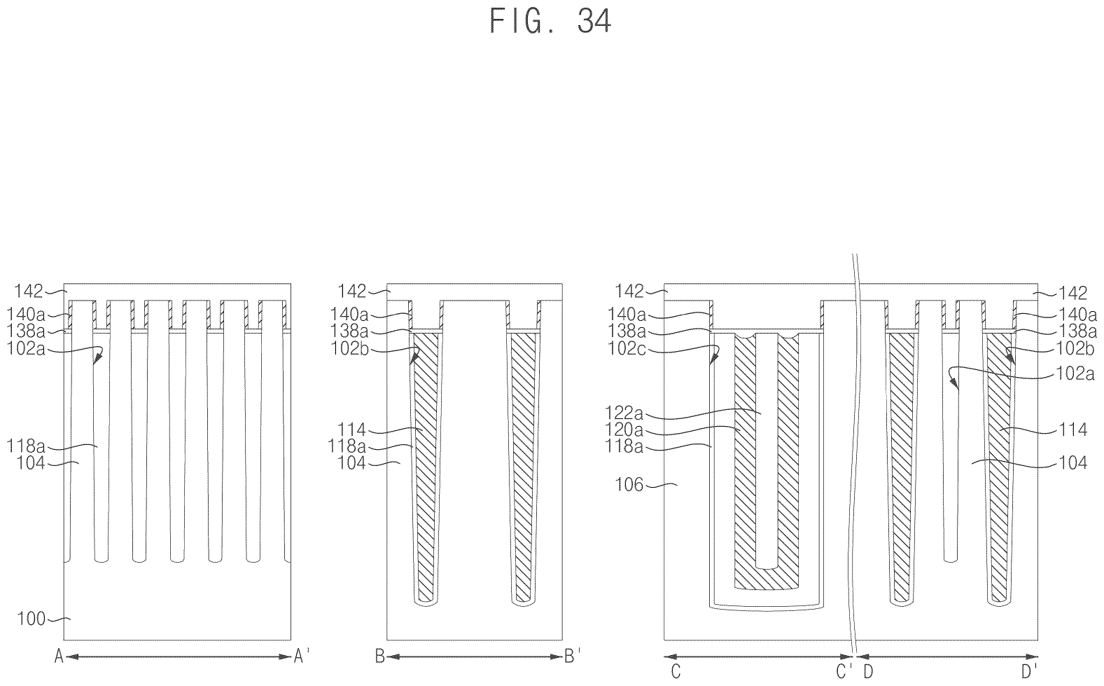

Referring to FIG. 34, the first capping insulation layer 142 may be formed on the first and second active patterns 104 and 106, the upper silicon pattern 140a, and the lower capping insulation pattern to fill the first recess 130.

The first capping insulation layer 142 may include, for example, silicon oxide. Since the lower capping insulation pattern 138a and the first capping insulation layer 142 include the same material, the lower capping insulation pattern 138a and the first capping insulation layer 142 may be merged into an insulation layer.

Thereafter, the processes described with reference to FIGS. 16 to 29 may be performed to manufacture the semiconductor device shown in FIG. 29.

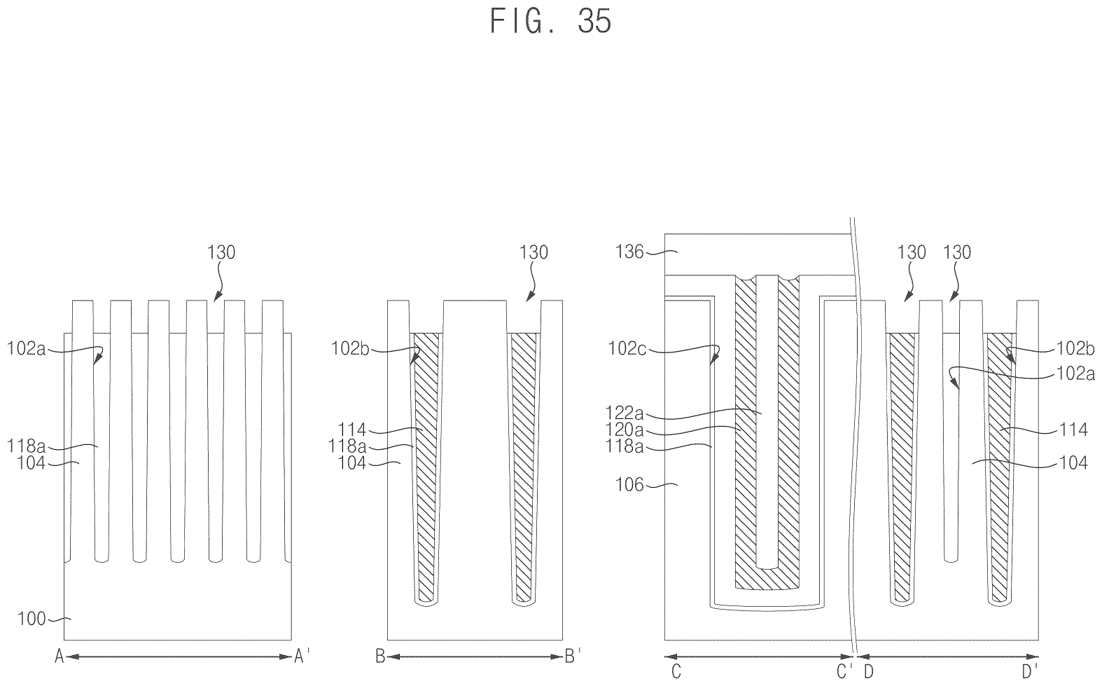

FIGS. 35 to 38 are cross-sectional views and plan views illustrating a method for manufacturing a semiconductor device according to example embodiments.

The method for manufacturing the semiconductor device may include the same or similar processes as those described with reference to FIGS. 1 to 29. Therefore, redundant descriptions may be omitted.

Referring to FIG. 35, first, the processes described with reference to FIGS. 1 to 7 may be performed.

A mask pattern 136 may be formed to cover the first to third filling insulation layers 118, 120, and 122 on the second region II. The mask pattern may include, for example, a photoresist pattern.

Thereafter, upper portions of the first filling insulation layer 118 and the second insulation layer pattern 114 on the first region I may be etched using the mask pattern 136 as an etching mask so as to expose the upper surface and the upper sidewall of the first active pattern.

Accordingly, the first filling insulation layer pattern 118a may be formed to fill the first trench 102a, and the first filling insulation layer pattern 118a and the second insulation layer pattern 114 may be formed to fill the second trench 102b. In addition, the first filling insulation layer 118, the second filling insulation layer 120, and the third filling insulation layer 122 may remain on the third trench 102c and the substrate 100 of the second region II.

When the etching process is performed, the first recesses 130 may be formed between the first active patterns 104. The device isolation layer may be exposed by the bottom of the first recesses 130. For example, on the first region I, the first filling insulation layer pattern 118a may be exposed by the first recess 130 corresponding to the first trench 102a. On the first region, the first filling insulation layer pattern 118a and the second insulation layer pattern 114 may be exposed by the first recess 130 corresponding to the second trench 102b.

The etching process may include, for example, an etch-back process or a wet etching process.

In the etching process, the first filling insulation layer 118, the second filling insulation layer 120, and the third filling insulation layer 122 on the second region II may be covered with the mask pattern, so that the first filling insulation layer 118, the second filling insulation layer 120, and the third filling insulation layer 122 on the second region II may not be removed.

Thereafter, the mask pattern may be removed.

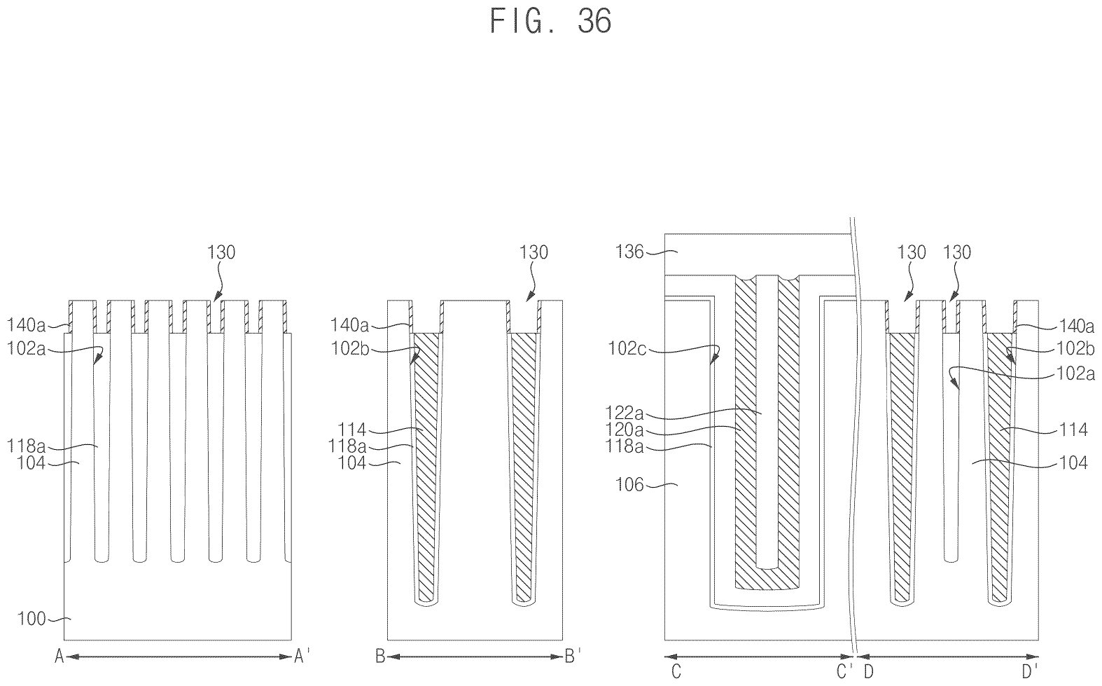

Referring to FIG. 36, the upper silicon layer may be conformally formed on an upper surface and an upper sidewall of the first active pattern 104, and surfaces of the first filling insulation layer pattern 118a and the second insulation layer pattern 114 on the bottom of the first recess 130.

Thereafter, the upper silicon layer may be anisotropically etched to form an upper silicon pattern 140a covering the upper sidewall of the first active patterns 104. The upper silicon pattern 140a may serve as an active region.

The upper silicon pattern 140 may not be formed on the upper surface and upper sidewalls of the second active pattern 106. An upper surface area of the second active pattern 106 may be greater than an upper surface area of the first active pattern 104, and thus an additional expansion of the upper surface area of the second active pattern 106 may not be necessary. Accordingly, the upper silicon pattern 140a may be formed only on the upper sidewall of the first active pattern 104.

The forming of the upper silicon layer and anisotropic etching of the upper silicon layer may be substantially the same as those described with reference to FIGS. 10 to 14.

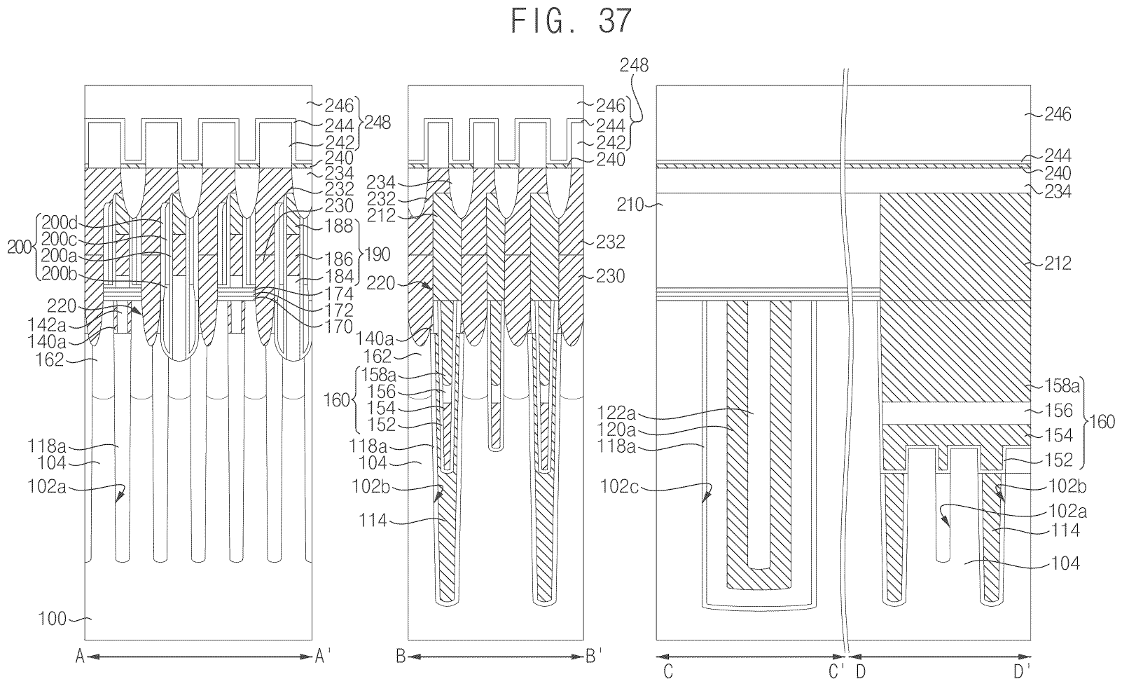

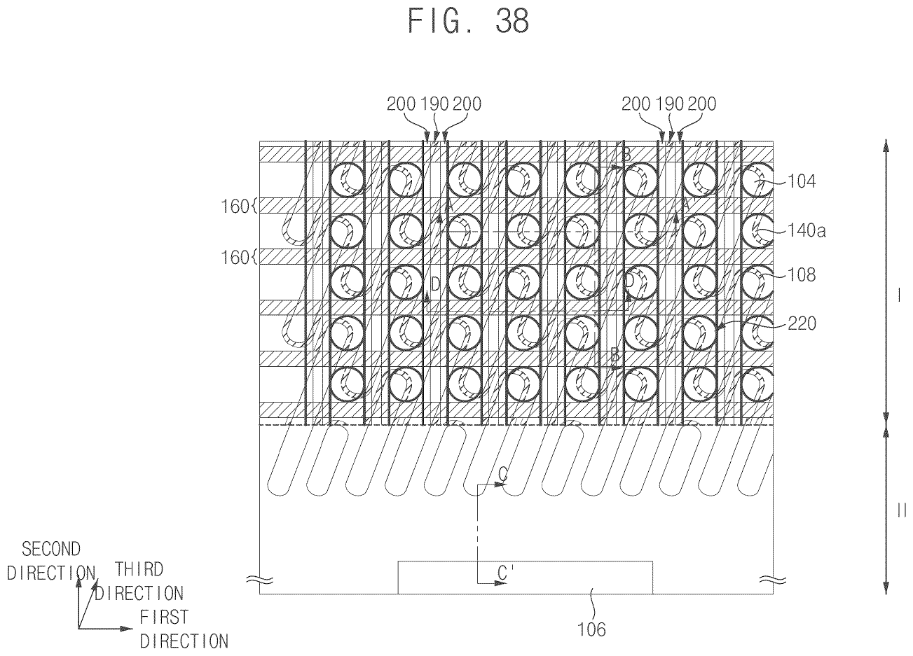

Substantially the same processes as those described with reference to FIGS. 15 to 29 may be performed to manufacture the semiconductor devices shown in FIGS. 37 and 38.

The semiconductor device manufactured by the above processes may not have the upper silicon pattern on the upper sidewall of the second active pattern 106 on the second region II. Additionally, the first capping insulation pattern may not be formed in the third trench 102c on the second region II. Other structure of the semiconductor device may be the same as the semiconductor device described with reference to FIG. 29.

In the semiconductor device, a portion of the first contact plug 230 contacting the upper edge in the third direction of the first active pattern 104 may contact the upper silicon pattern 140a. Accordingly, the contact region between the first contact plug 230 and the active region may be increased, and the contact resistance between first contact plug 230 and the active region may be decreased.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

The foregoing is illustrative of various example embodiments and is not to be construed as limiting thereof. Although a few example embodiments have been described, those skilled in the art will readily appreciate that many modifications are possible in the example embodiments without materially departing from the novel teachings and advantages of the present inventive concepts.

What is claimed is:

1. A semiconductor device, comprising:
a substrate including first active patterns, the substrate defining trenches between the first active patterns;
an upper silicon pattern on an upper sidewall of at least a portion of each of the first active patterns; and
a first contact plug contacting an edge portion in a longitudinal direction of each of the first active patterns, a sidewall of the first contact plug contacting at least a portion of the upper silicon pattern, and the first contact plug having a bottom lower than a bottom of the upper silicon pattern.

2. The semiconductor device of claim 1, further comprising:
a device isolation pattern filling each of the trenches, and
wherein the upper silicon pattern is on a sidewall of each of the first active patterns above an upper surface of the device isolation pattern.

3. The semiconductor device of claim 2, further comprising:
a first capping insulation pattern on the device isolation pattern to fill each of the trenches between the upper silicon patterns on opposing sidewalls of the first active patterns.

4. The semiconductor device of claim 1, wherein the upper silicon pattern includes polysilicon.

5. The semiconductor device of claim 1, further comprising:
a gate structure in the substrate, extending in a first direction; and
a bit line structure on the substrate, extending in a second direction perpendicular to the first direction.

6. The semiconductor device of claim 5, wherein the first contact plug contacts a respective one of the first active patterns and the first silicon pattern between the gate structure and the bit line structure.

7. The semiconductor device of claim 5, wherein
a portion of the bottom of the bit line structure contacts a central portion in the longitudinal direction of the first active patterns, and
the bottom of the bit line structure contacting the central portion in the longitudinal direction is lower than a bottom of the upper silicon pattern.

8. The semiconductor device of claim 5, wherein the upper silicon patterns are each on a respective upper sidewall of the first active patterns outside of the first contact plugs from an outer wall of the gate structure.

9. A semiconductor device, comprising:
a substrate;
first trenches defined by a first region of the substrate;
first active patterns between the first trenches;
second trenches defined by a second region of the substrate;
second active patterns between the second trenches;
a first device isolation pattern in the first trenches;
a second device isolation pattern in the second trenches;
an upper silicon pattern on an upper sidewall of at least a portion of each of the first active patterns;
a gate structure in the substrate of the first region, extending in a first direction;
a bit line structure on the first region of the substrate, extending in a second direction perpendicular to the first direction, and contacting a central portion in a longitudinal direction of the first active patterns; and
a first contact plug contacting an edge portion in the longitudinal direction of the first active patterns, a sidewall of the first contact plug contacting at least a portion of the upper silicon pattern, and the first contact plug having a bottom lower than a bottom of the upper silicon pattern.

10. The semiconductor device of claim 9, wherein a bottom of the bit line structure contacting the central portion in the longitudinal direction of the first active patterns is lower than a bottom of the upper silicon pattern.

11. The semiconductor device of claim 9, wherein the first contact plug contacts a respective one of the first active patterns and the first silicon pattern between the gate structure and the bit line structure.

12. The semiconductor device of claim 9, wherein the upper silicon pattern is on a sidewall of the first active patterns above an upper surface of the first device isolation pattern.

13. The semiconductor device of claim 9, further comprising:
a first capping insulation pattern on the first device isolation pattern filling the first trenches between the upper silicon patterns.

14. The semiconductor device of claim 9, wherein the upper silicon pattern is on upper sidewalls of the second active patterns.

15. The semiconductor device of claim 14, further comprising:
a second capping insulation pattern on the second device isolation pattern filling the second trenches between the upper silicon patterns.

16. The semiconductor device of claim 9, further comprising:
a landing pad pattern on the first contact plug; and
a capacitor on the landing pad pattern.

17. A semiconductor device, comprising:
a substrate;
first trenches defined by the substrate;
first active patterns between the first trenches;
a first device isolation pattern in the first trenches, an upper surface of the first device isolation being lower than upper surfaces of the first active patterns;
an upper silicon pattern on an upper sidewall of the first active patterns above the upper surface of the first device isolation pattern;
a capping insulation pattern between the upper silicon patterns on the first device isolation pattern;
a gate structure in the substrate, extending in a first direction;
a bit line structure on the substrate, extending in a second direction perpendicular to the first direction, and contacting a central portion in a longitudinal direction of the first active patterns; and
a first contact plug contacting an edge portion in the longitudinal direction of the first active patterns, a sidewall of the first contact plug contacting at least a portion of the upper silicon pattern, and the first contact plug having a bottom lower than a bottom of the upper silicon pattern.

18. The semiconductor device of claim 17, further comprising:
an impurity region at each of the first active patterns adjacent to both sides of the gate structure,
wherein a bottom of the first contact plug is higher than a bottom of the impurity region.

19. The semiconductor device of claim 17, wherein the upper silicon pattern is on an upper sidewall of the first active patterns outside of the first contact plugs from an outer wall of the gate structure.

20. The semiconductor device of claim 17, wherein an upper surface of the first capping insulation pattern is coplanar with an uppermost surface of the upper silicon pattern.
